(19) United States
(12) Patent Application Publication
(10) Pub. No.: US 2026/0090006 A1
(43) Pub. Date: Mar. 26, 2026

(54) SEMICONDUCTOR DEVICE, SEMICONDUCTOR MEMORY DEVICE, AND METHOD FOR MANUFACTURING SEMICONDUCTOR DEVICE

(71) Applicant: KIOXIA CORPORATION, Tokyo (JP)

(72) Inventor: Yusuke KASAHARA, Yokkaichi Mie (JP)

(73) Assignee: KIOXIA CORPORATION, Tokyo (JP)

(21) Appl. No.: 19/083,528

(22) Filed: Mar. 19, 2025

(30) Foreign Application Priority Data
Sep. 20, 2024 (JP) 2024-163634

(51) Int. Cl. H10D 30/63; H10B 12/00; H10D 62/10; H10D 64/27

(52) U.S. Cl. CPC H10D 30/63; H10B 12/05; H10B 12/33; H10D 62/115; H10D 62/124; H10D 64/519

(57) ABSTRACT

A semiconductor device according to an embodiment includes: a first electrode; a second electrode; an oxide semiconductor layer between the first electrode and the second electrode; and a gate electrode facing the oxide semiconductor layer. The gate electrode includes a first portion and a second portion sandwiching the oxide semiconductor layer between them. The distance between an inner side of the first portion and an inner side of the second portion decreases from the first electrode side towards the second electrode side. The distance between an outer side of the first portion and an outer side of the second portion decreases from the first electrode side towards the second electrode side.

### CROSS-REFERENCE TO RELATED APPLICATION

This application is based upon and claims the benefit of priority from Japanese Patent Application No. 2024-163634, filed on Sep. 20, 2024, the entire contents of which are incorporated herein by reference.

### FIELD

Embodiments described herein relate generally to a semiconductor device, a semiconductor memory device, and a method for manufacturing a semiconductor device.

### BACKGROUND

An oxide semiconductor transistor in which a channel is formed in an oxide semiconductor layer has an excellent characteristic that a channel leakage current during off-operation is extremely small. Therefore, for example, the oxide semiconductor transistor can be applied to a switching transistor of a memory cell of a dynamic random access memory (DRAM).

### BRIEF DESCRIPTION OF THE DRAWINGS

FIG. 1 is a schematic cross-sectional view of a semiconductor device according to a first embodiment;

FIG. 2 is a schematic cross-sectional view of the semiconductor device according to the first embodiment;

FIG. 3 is an explanatory diagram of an example of a shape of a gate electrode of the semiconductor device according to the first embodiment;

FIG. 4 is a schematic cross-sectional view illustrating an example of a method for manufacturing the semiconductor device according to the first embodiment;

FIG. 5 is a schematic cross-sectional view illustrating an example of the method for manufacturing the semiconductor device according to the first embodiment;

FIG. 6 is a schematic cross-sectional view illustrating an example of the method for manufacturing the semiconductor device according to the first embodiment;

FIG. 7 is a schematic cross-sectional view illustrating an example of the method for manufacturing the semiconductor device according to the first embodiment;

FIG. 8 is a schematic cross-sectional view illustrating an example of the method for manufacturing the semiconductor device according to the first embodiment;

FIG. 9 is a schematic cross-sectional view illustrating an example of the method for manufacturing the semiconductor device according to the first embodiment;

FIG. 10 is a schematic cross-sectional view illustrating an example of the method for manufacturing the semiconductor device according to the first embodiment;

FIG. 11 is a schematic cross-sectional view illustrating an example of the method for manufacturing the semiconductor device according to the first embodiment;

FIG. 12 is a schematic cross-sectional view illustrating an example of the method for manufacturing the semiconductor device according to the first embodiment;

FIG. 13 is a schematic cross-sectional view illustrating an example of the method for manufacturing the semiconductor device according to the first embodiment;

FIG. 14 is a schematic cross-sectional view illustrating an example of the method for manufacturing the semiconductor device according to the first embodiment;

FIG. 15 is a schematic cross-sectional view illustrating an example of the method for manufacturing the semiconductor device according to the first embodiment;

FIG. 16 is a schematic cross-sectional view illustrating an example of the method for manufacturing the semiconductor device according to the first embodiment;

FIG. 17 is a schematic cross-sectional view illustrating an example of the method for manufacturing the semiconductor device according to the first embodiment;

FIG. 18 is a schematic cross-sectional view illustrating an example of the method for manufacturing the semiconductor device according to the first embodiment;

FIG. 19 is a schematic cross-sectional view illustrating an example of the method for manufacturing the semiconductor device according to the first embodiment;

FIG. 20 is a schematic cross-sectional view illustrating an example of the method for manufacturing the semiconductor device according to the first embodiment;

FIG. 21 is a schematic cross-sectional view illustrating an example of the method for manufacturing the semiconductor device according to the first embodiment;

FIG. 22 is a schematic cross-sectional view illustrating an example of the method for manufacturing the semiconductor device according to the first embodiment;

FIG. 23 is an explanatory diagram of functions and effects of the semiconductor device and the method for manufacturing the semiconductor device according to the first embodiment;

FIG. 24 is an explanatory diagram of functions and effects of the semiconductor device and the method for manufacturing the semiconductor device according to the first embodiment;

FIG. 25 is a schematic cross-sectional view of a semiconductor device according to a modification of the first embodiment;

FIG. 26 is a schematic cross-sectional view illustrating an example of a method for manufacturing a semiconductor device according to a second embodiment;

FIG. 27 is a schematic cross-sectional view illustrating an example of the method for manufacturing the semiconductor device according to the second embodiment;

FIG. 28 is a schematic cross-sectional view illustrating an example of the method for manufacturing the semiconductor device according to the second embodiment;

FIG. 29 is a schematic cross-sectional view illustrating an example of the method for manufacturing the semiconductor device according to the second embodiment;

FIG. 30 is a schematic cross-sectional view illustrating an example of the method for manufacturing the semiconductor device according to the second embodiment;

FIG. 31 is an explanatory diagram of functions and effects of the method for manufacturing the semiconductor device according to the second embodiment;

FIG. 32 is an explanatory diagram of functions and effects of the method for manufacturing the semiconductor device according to the second embodiment;

FIG. 33 is a schematic cross-sectional view of a semiconductor device according to a third embodiment;

FIG. 34 is a schematic cross-sectional view illustrating an example of a method for manufacturing the semiconductor device according to the third embodiment;

FIG. 35 is a schematic cross-sectional view illustrating an example of the method for manufacturing the semiconductor device according to the third embodiment;

FIG. 36 is a schematic cross-sectional view illustrating an example of the method for manufacturing the semiconductor device according to the third embodiment;

FIG. 37 is a schematic cross-sectional view illustrating an example of the method for manufacturing the semiconductor device according to the third embodiment;

FIG. 38 is a schematic cross-sectional view illustrating an example of the method for manufacturing the semiconductor device according to the third embodiment;

FIG. 39 is a schematic cross-sectional view illustrating an example of the method for manufacturing the semiconductor device according to the third embodiment;

FIG. 40 is a schematic cross-sectional view illustrating an example of the method for manufacturing the semiconductor device according to the third embodiment;

FIG. 41 is a schematic cross-sectional view illustrating an example of the method for manufacturing the semiconductor device according to the third embodiment;

FIG. 42 is a schematic cross-sectional view illustrating an example of the method for manufacturing the semiconductor device according to the third embodiment;

FIG. 43 is a schematic cross-sectional view illustrating an example of the method for manufacturing the semiconductor device according to the third embodiment;

FIG. 44 is a schematic cross-sectional view illustrating an example of the method for manufacturing the semiconductor device according to the third embodiment;

FIG. 45 is a schematic cross-sectional view illustrating an example of the method for manufacturing the semiconductor device according to the third embodiment;

FIG. 46 is a schematic cross-sectional view illustrating an example of the method for manufacturing the semiconductor device according to the third embodiment;

FIG. 47 is a schematic cross-sectional view illustrating an example of the method for manufacturing the semiconductor device according to the third embodiment;

FIG. 48 is a schematic cross-sectional view illustrating an example of the method for manufacturing the semiconductor device according to the third embodiment;

FIG. 49 is a schematic cross-sectional view illustrating an example of the method for manufacturing the semiconductor device according to the third embodiment;

FIG. 50 is a schematic cross-sectional view illustrating an example of the method for manufacturing the semiconductor device according to the third embodiment;

FIG. 51 is a schematic cross-sectional view illustrating an example of the method for manufacturing the semiconductor device according to the third embodiment;

FIG. 52 is a schematic cross-sectional view illustrating an example of the method for manufacturing the semiconductor device according to the third embodiment;

FIG. 53 is a schematic cross-sectional view illustrating an example of the method for manufacturing the semiconductor device according to the third embodiment;

FIG. 54 is an equivalent circuit diagram of a semiconductor memory device according to a fourth embodiment; and

FIG. 55 is a schematic cross-sectional view of the semiconductor memory device according to the fourth embodiment.

### DETAILED DESCRIPTION

A semiconductor device according to an embodiment includes: a first electrode; a second electrode; an oxide semiconductor layer provided between the first electrode and the second electrode; a gate electrode facing the oxide semiconductor layer; and a gate insulating layer provided between the gate electrode and the oxide semiconductor layer. In a first cross section parallel to a first direction connecting the first electrode and the second electrode, the gate electrode includes a first portion and a second portion. The oxide semiconductor layer is provided between the first portion and the second portion in a second direction perpendicular to the first direction. The first portion has a first end portion on a side of the first electrode and a second end portion on a side of the second electrode, the first end portion having a first end point in contact with the gate insulating layer and a second end point on an opposite side of the first end point, and the second end portion having a third end point in contact with the gate insulating layer and a fourth end point on an opposite side of the third end point. The second portion has a third end portion on a side of the first electrode and a fourth end portion on a side of the second electrode, the third end portion having a fifth end point in contact with the gate insulating layer and a sixth end point on an opposite side of the fifth end point, and the fourth end portion having a seventh end point in contact with the gate insulating layer and an eighth end point on an opposite side of the seventh end point. A first distance between the first end point and the fifth end point is larger than a second distance between the third end point and the seventh end point, and a third distance between the second end point and the sixth end point is larger than a fourth distance between the fourth end point and the eighth end point.

Hereinafter, embodiments of the present disclosure will be described with reference to the drawings. In the following description, the same or similar members are denoted by the same reference numerals and the description of the members described once is appropriately omitted.

In the present specification, a term “above”, “below”, “upper”, or “lower” may be used for convenience. The term “above”, “below”, “upper”, or “lower” is a term that indicates a relative positional relation in the drawings, but does not define a positional relation with respect to gravity.

The qualitative analysis and the quantitative analysis of chemical compositions of members forming a semiconductor device and a semiconductor memory device in the present specification can be carried out by secondary ion mass spectrometry (SIMS), energy dispersive X-ray spectroscopy (EDX), and Rutherford back-scattering spectroscopy (RBS), for example. For measurement of a thickness of the members forming the semiconductor device and the semiconductor memory device, a distance between the members, a crystal grain size, and the like, for example, a transmission electron microscope (TEM) can be used. For identification of constituent substances of the members forming the semiconductor device and the semiconductor memory device and measurement of existence ratios of the constituent substances, for example, X-ray photoelectron spectroscopy (XPS), hard X-ray photoelectron spectroscopy (HAXPES), and electron energy loss spectroscopy (EELS) can be used.

In the present specification, a term “metal” is a general term for substances exhibiting metallic properties, and for example, metal compounds such as metal nitrides and metal carbides exhibiting metallic properties are also included in a range of “metal”.

### First Embodiment

A semiconductor device according to a first embodiment includes a first electrode, a second electrode, an oxide semiconductor layer provided between the first electrode and the second electrode, a gate electrode facing the oxide semiconductor layer, and a gate insulating layer provided between the gate electrode and the oxide semiconductor layer. In a first cross section parallel to a first direction connecting the first electrode and the second electrode, the gate electrode includes a first portion and a second portion. The oxide semiconductor layer is provided between the first portion and the second portion in a second direction perpendicular to the first direction. The first portion has a first end portion on a side of the first electrode and a second end portion on a side of the second electrode, the first end portion has a first end point in contact with the gate insulating layer and a second end point on an opposite side of the first end point, and the second end portion has a third end point in contact with the gate insulating layer and a fourth end point on an opposite side of the third end point. The second portion has a third end portion on a side of the first electrode and a fourth end portion on a side of the second electrode, the third end portion has a fifth end point in contact with the gate insulating layer and a sixth end point on an opposite side of the fifth end point, and the fourth end portion has a seventh end point in contact with the gate insulating layer and an eighth end point on an opposite side of the seventh end point. A first distance between the first end point and the fifth end point is larger than a second distance between the third end point and the seventh end point, and a third distance between the second end point and the sixth end point is larger than a fourth distance between the fourth end point and the eighth end point.

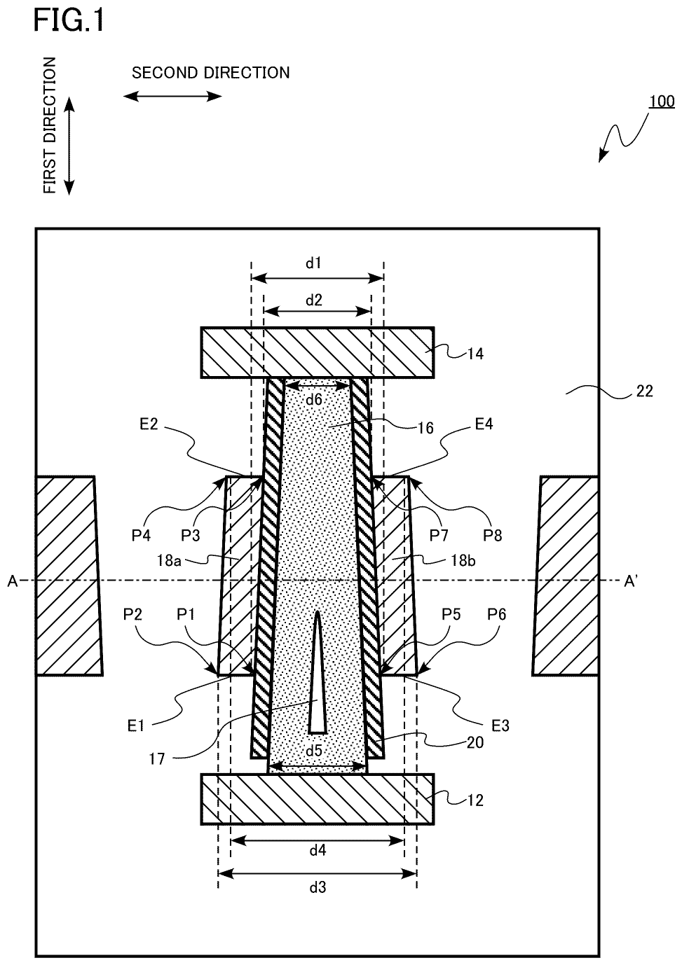

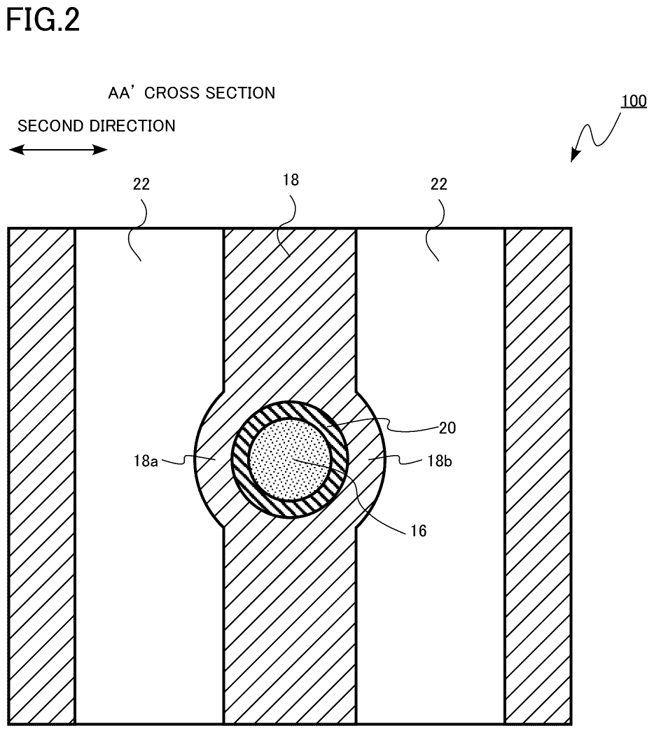

FIGS. 1 and 2 are schematic cross-sectional views of the semiconductor device according to the first embodiment. FIG. 2 is a cross-sectional view taken along the line AA′ of FIG. 1. In FIG. 1, an up-down direction is referred to as a first direction. In FIG. 1, a left-right direction is referred to as a second direction. The second direction is perpendicular to the first direction. The first direction is a direction connecting a lower electrode 12 and an upper electrode 14.

FIG. 1 illustrates a cross section parallel to the first direction. FIG. 1 illustrates an example of the first cross section.

The semiconductor device according to the first embodiment is a transistor 100. The transistor 100 is an oxide semiconductor transistor in which a channel is formed in an oxide semiconductor. In the transistor 100, a gate electrode is provided to surround the oxide semiconductor layer in which the channel is formed. The transistor 100 is a so-called surrounding gate transistor (SGT). The transistor 100 is a so-called vertical transistor.

The transistor 100 includes a lower electrode 12, an upper electrode 14, an oxide semiconductor layer 16, a gate electrode 18, a gate insulating layer 20, and an interlayer insulating layer 22. The gate electrode 18 includes a first portion 18a and a second portion 18b.

The lower electrode 12 is an example of the first electrode. The upper electrode 14 is an example of the second electrode.

The lower electrode 12 is provided below the oxide semiconductor layer 16. The lower electrode 12 is electrically connected to the oxide semiconductor layer 16. The lower electrode 12 is in contact with, for example, the oxide semiconductor layer 16. The lower electrode 12 functions as a source electrode or a drain electrode of the transistor 100.

The lower electrode 12 is a conductor. The lower electrode 12 includes, for example, an oxide conductor. The lower electrode 12 is, for example, an oxide conductor layer.

The lower electrode 12 contains, for example, indium (In), tin (Sn), and oxygen (O). The lower electrode 12 contains, for example, indium tin oxide. The lower electrode 12 is, for example, an indium tin oxide layer.

The lower electrode 12 contains, for example, tin (Sn) and oxygen (O). The lower electrode 12 contains, for example, tin oxide. The lower electrode 12 is, for example, a tin oxide layer.

The lower electrode 12 contains, for example, a metal. The lower electrode 12 is, for example, a metal layer.

The lower electrode 12 contains, for example, tungsten (W), molybdenum (Mo), copper (Cu), aluminum (Al), titanium (Ti), or tantalum (Ta). The lower electrode 12 is, for example, a tungsten layer, a molybdenum layer, a copper layer, an aluminum layer, a titanium layer, or a tantalum layer.

The lower electrode 12 may have, for example, a stacked structure of a plurality of conductors. The lower electrode 12 has, for example, a stacked structure of an oxide conductor layer and a metal layer. For example, a surface of the lower electrode 12 on the oxide semiconductor layer 16 side is an oxide conductor layer.

The upper electrode 14 is provided on the oxide semiconductor layer 16. The upper electrode 14 is electrically connected to the oxide semiconductor layer 16. The upper electrode 14 is in contact with, for example, the oxide semiconductor layer 16. The upper electrode 14 functions as the source electrode or the drain electrode of the transistor 100.

The upper electrode 14 is a conductor. The upper electrode 14 includes, for example, an oxide conductor. The upper electrode 14 is, for example, an oxide conductor layer.

The upper electrode 14 contains, for example, indium (In), tin (Sn), and oxygen (O). The upper electrode 14 contains, for example, indium tin oxide. The upper electrode 14 is, for example, an indium tin oxide layer.

The upper electrode 14 contains, for example, tin (Sn) and oxygen (O). The upper electrode 14 contains, for example, tin oxide. The upper electrode 14 is, for example, a tin oxide layer.

The upper electrode 14 contains, for example, a metal. The upper electrode 14 is, for example, a metal layer.

The upper electrode 14 contains, for example, tungsten (W), molybdenum (Mo), copper (Cu), aluminum (Al), titanium (Ti), or tantalum (Ta). The upper electrode 14 is, for example, a tungsten layer, a molybdenum layer, a copper layer, an aluminum layer, a titanium layer, or a tantalum layer.

The upper electrode 14 may have, for example, a stacked structure of a plurality of conductors. The upper electrode 14 has, for example, a stacked structure of an oxide conductor layer and a metal layer. For example, a surface of the upper electrode 14 on the oxide semiconductor layer 16 side is an oxide conductor layer.

The lower electrode 12 and the upper electrode 14 are formed of, for example, the same material. The lower electrode 12 and the upper electrode 14 are, for example, oxide conductors containing indium (In), tin (Sn), and oxygen (O). The lower electrode 12 and the upper electrode 14 contain, for example, indium tin oxide. The lower electrode 12 and the upper electrode 14 are, for example, indium tin oxide layers.

The oxide semiconductor layer 16 is provided between the lower electrode 12 and the upper electrode 14. The oxide semiconductor layer 16 is in contact with, for example, the lower electrode 12. The oxide semiconductor layer 16 is in contact with, for example, the upper electrode 14.

The oxide semiconductor layer 16 is provided with a channel functioning as a current path when the transistor 100 is turned on.

The oxide semiconductor layer 16 is an oxide semiconductor. The oxide semiconductor layer 16 is, for example, amorphous.

The oxide semiconductor layer 16 contains, for example, at least one element selected from the group consisting of indium (In), gallium (Ga), silicon (Si), aluminum (Al), and tin (Sn), zinc (Zn), and oxygen (O). The oxide semiconductor layer 16 contains, for example, indium (In), gallium (Ga), zinc (Zn), and oxygen (O). The oxide semiconductor layer 16 contains, for example, indium gallium zinc oxide. The oxide semiconductor layer 16 is, for example, an indium gallium zinc oxide layer.

The oxide semiconductor layer 16 contains, for example, at least one element selected from the group consisting of titanium (Ti), zinc (Zn), and tungsten (W) and oxygen (O). The oxide semiconductor layer 16 contains, for example, titanium oxide, zinc oxide, or tungsten oxide. The oxide semiconductor layer 16 is, for example, a titanium oxide layer, a zinc oxide layer, or a tungsten oxide layer.

The oxide semiconductor layer 16 has, for example, a chemical composition different from the chemical composition of the lower electrode 12 and the chemical composition of the upper electrode 14.

The oxide semiconductor layer 16 includes oxygen vacancies. The oxygen vacancies in the oxide semiconductor layer 16 function as donors.

A length of the oxide semiconductor layer 16 in the first direction is, for example, equal to or more than 80 nm and equal to or less than 200 nm. A length of the oxide semiconductor layer 16 in the second direction is, for example, equal to or more than 10 nm and equal to or less than 100 nm.

A fifth distance (d5 in FIG. 1) in the second direction of a portion of the oxide semiconductor layer 16 in contact with the lower electrode 12 is larger than a sixth distance (d6 in FIG. 1) in the second direction of a portion of the oxide semiconductor layer 16 in contact with the upper electrode 14. The fifth distance d5 is, for example, 1.1 times or more and 3 times or less the sixth distance d6.

A width in the second direction of a portion sandwiched between the gate insulating layers 20 on both sides of the oxide semiconductor layer 16 increases from the upper electrode 14 toward the lower electrode 12. The oxide semiconductor layer 16 has a so-called reverse tapered shape.

The oxide semiconductor layer 16 includes a void 17.

The gate electrode 18 faces the oxide semiconductor layer 16. The gate electrode 18 is provided such that a position coordinate in the first direction is a value between position coordinates in the first direction of the lower electrode 12 and the upper electrode 14.

As illustrated in FIG. 2, the gate electrode 18 is provided to surround the oxide semiconductor layer 16. The gate electrode 18 is provided around the oxide semiconductor layer 16.

The gate electrode 18 is a conductor. The gate electrode 18 is, for example, a metal, a metal compound, or a semiconductor. The gate electrode 18 contains, for example, tungsten (W).

A length of the gate electrode 18 in the first direction is, for example, equal to or more than 10 nm and equal to or less than 100 nm.

The gate electrode 18 includes the first portion 18a and the second portion 18b in a cross section parallel to the first direction. In the second direction, the oxide semiconductor layer 16 is provided between the first portion 18a and the second portion 18b.

The first portion 18a has a first end portion E1 on the lower electrode 12 side and a second end portion E2 on the upper electrode 14 side. The first end portion E1 has a first end point P1 in contact with the gate insulating layer 20 and a second end point P2 opposite to the first end point P1. The second end portion E2 has a third end point P3 in contact with the gate insulating layer 20 and a fourth end point P4 opposite to the third end point P3.

The second portion 18b has a third end portion E3 on the lower electrode 12 side and a fourth end portion E4 on the upper electrode 14 side. The third end portion E3 has a fifth end point P5 in contact with the gate insulating layer 20 and a sixth end point P6 opposite to the fifth end point P5. The fourth end portion E4 has a seventh end point P7 in contact with the gate insulating layer 20 and an eighth end point P8 opposite to the seventh end point P7.

A first distance (d1 in FIG. 1) between the first end point P1 and the fifth end point P5 is larger than a second distance (d2 in FIG. 1) between the third end point P3 and the seventh end point P7. In addition, a third distance (d3 in FIG. 1) between the second end point P2 and the sixth end point P6 is larger than a fourth distance (d4 in FIG. 1) between the fourth end point P4 and the eighth end point P8.

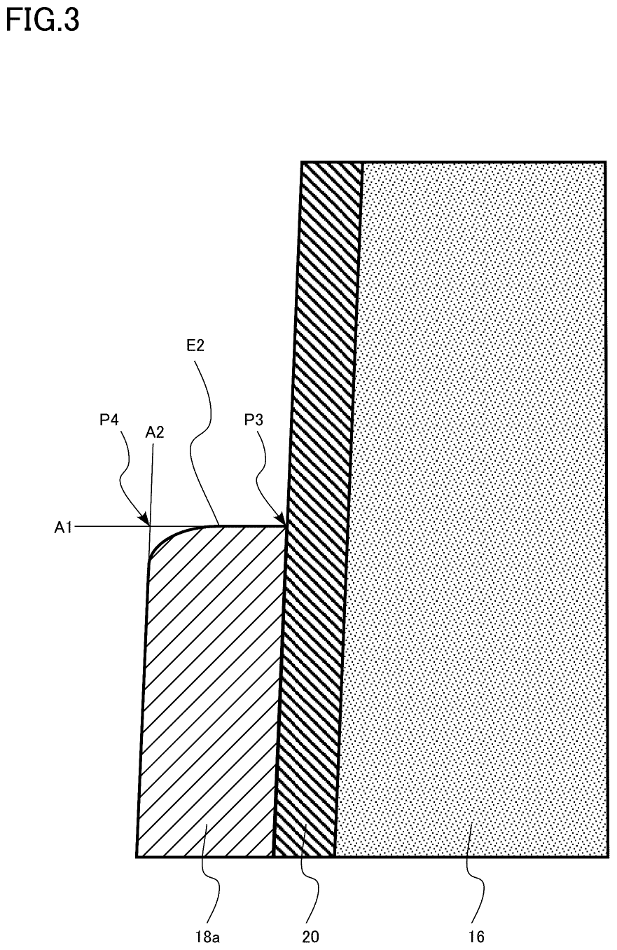

FIG. 3 is an explanatory diagram of an example of a shape of the gate electrode of the semiconductor device according to the first embodiment. FIG. 3 is an enlarged view illustrating an example of the second end portion E2 of the first portion 18a of the gate electrode 18.

It is assumed that a corner of the second end portion E2 of the first portion 18a on the side opposite to the oxide semiconductor layer 16 is rounded as illustrated in FIG. 3. In this case, it is assumed that an intersection of a line segment A1 obtained by extending a linear portion of a top surface of the second end portion E2 from the third end point P3 of the second end portion E2 and a line segment A2 obtained by extending a linear portion of a side surface of the first portion 18a is defined as the fourth end point P4.

As illustrated in FIG. 1, the distance in the second direction between the first portion 18a and the second portion 18b of the gate electrode 18 sandwiching the oxide semiconductor layer 16 increases from the upper electrode 14 toward the lower electrode 12 in both an inner surface on the oxide semiconductor layer 16 side and an outer surface on the opposite side of the oxide semiconductor layer 16.

The gate insulating layer 20 is provided between the oxide semiconductor layer 16 and the gate electrode 18. The gate insulating layer 20 is provided so as to surround the oxide semiconductor layer 16. The gate insulating layer 20 is provided between the lower electrode 12 and the upper electrode 14.

The gate insulating layer 20 is not in contact with, for example, the lower electrode 12. The gate insulating layer 20 is in contact with, for example, the upper electrode 14.

The gate insulating layer 20 is, for example, an oxide, a nitride, or an oxynitride. The gate insulating layer 20 includes, for example, silicon oxide, aluminum oxide, silicon nitride, aluminum nitride, or silicon oxynitride. The gate insulating layer 20 is, for example, a silicon oxide layer, an aluminum oxide layer, a silicon nitride layer, an aluminum nitride layer, or a silicon oxynitride layer.

The gate insulating layer 20 may have, for example, a stacked structure. The gate insulating layer 20 has, for example, a stacked structure of nitride and oxide. The gate insulating layer 20 has, for example, a stacked structure of a silicon nitride layer and a silicon oxide layer. The thickness of the gate insulating layer 20 is, for example, equal to or more than 2 nm and equal to or less than 10 nm.

The lower electrode 12 is separated from the gate insulating layer 20 in the first direction, for example. In the first direction, the interlayer insulating layer 22 is provided between the lower electrode 12 and the gate insulating layer 20, for example.

The interlayer insulating layer 22 surrounds, for example, the lower electrode 12, the upper electrode 14, the oxide semiconductor layer 16, and the gate insulating layer 20. The interlayer insulating layer 22 is provided, for example, between the lower electrode 12 and the gate electrode 18. The interlayer insulating layer 22 is provided, for example, between the upper electrode 14 and the gate electrode 18.

The interlayer insulating layer 22 is an insulator. The interlayer insulating layer 22 is, for example, an oxide, a nitride, or an oxynitride. The interlayer insulating layer 22 contains, for example, silicon (Si) and oxygen (O). The interlayer insulating layer 22 is, for example, silicon oxide. The interlayer insulating layer 22 is, for example, silicon oxide. The interlayer insulating layer 22 contains, for example, silicon (Si) and nitrogen (N). The interlayer insulating layer 22 is, for example, silicon oxide. The interlayer insulating layer 22 is, for example, silicon oxide.

Next, an example of a method for manufacturing the semiconductor device according to the first embodiment will be described.

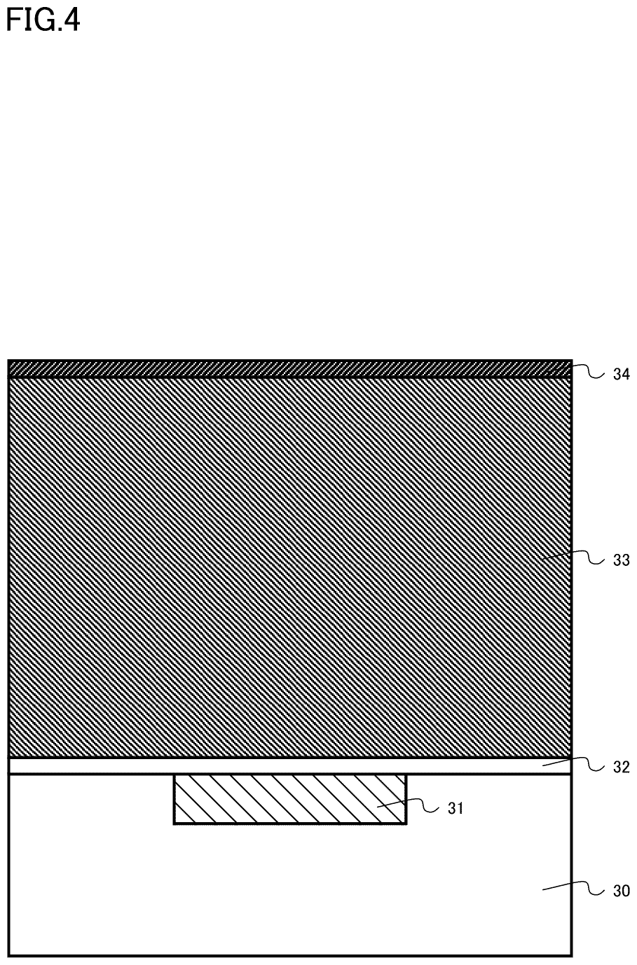

FIGS. 4 to 22 are schematic cross-sectional views illustrating an example of the method for manufacturing the semiconductor device according to the first embodiment. Each of FIGS. 4 to 22 illustrates a cross section corresponding to FIG. 1. FIGS. 4 to 22 are diagrams illustrating an example of a method for manufacturing the transistor 100.

Hereinafter, a case where the lower electrode 12 of the transistor 100 is an indium tin oxide layer, the upper electrode 14 is an indium tin oxide layer, the oxide semiconductor layer 16 is an indium gallium zinc oxide layer, the gate electrode 18 is a tungsten layer, the gate insulating layer 20 is a silicon oxide layer, and the interlayer insulating layer 22 is a silicon nitride layer and a silicon oxide layer will be described as an example.

As an example, the method for manufacturing the semiconductor device according to the first embodiment includes: forming a first film on a first conductive layer; etching the first film to form a columnar body in which a first width on a side of the first conductive layer is larger than a second width on an opposite side of the first conductive layer; burying the columnar body with a first insulating film; etching a part of the first insulating film to expose a part of the columnar body; burying the columnar body with a first metal film; etching a part of the first metal film to expose a part of the columnar body; covering the columnar body with a second insulating film; etching the second insulating film to form a sidewall on a side surface of the columnar body; burying the columnar body and the sidewall with a third insulating film; etching the third insulating film to form a first opening through which the sidewall and the first metal film are exposed; etching the first metal film using the third insulating film and the sidewall as a mask; burying the first opening with a fourth insulating film; removing the fourth insulating film on the columnar body; exposing the columnar body; etching and removing the columnar body to form a second opening through which the first metal film is exposed on a side surface; forming a fifth insulating film in the second opening; etching and removing the fifth insulating film at a bottom of the second opening; and burying the second opening with a semiconductor film. Further, when the fifth insulating film at the bottom of the second opening is etched, the first conductive layer is exposed.

First, a first silicon oxide film 32, an amorphous silicon film 33, and a first silicon nitride film 34 are formed on the indium tin oxide layer 31 formed in the silicon nitride layer 30 (FIG. 4). The first silicon oxide film 32, the amorphous silicon film 33, and the first silicon nitride film 34 are formed by, for example, a chemical vapor deposition method (CVD method). Note that an aluminum oxide film may be formed instead of the first silicon oxide film 32.

The silicon nitride layer 30 finally becomes the interlayer insulating layer 22. The indium tin oxide layer 31 finally becomes the lower electrode 12. A part of the first silicon oxide film 32 finally becomes the interlayer insulating layer 22. The indium tin oxide layer 31 is an example of the first conductive layer. The amorphous silicon film 33 is an example of the first film.

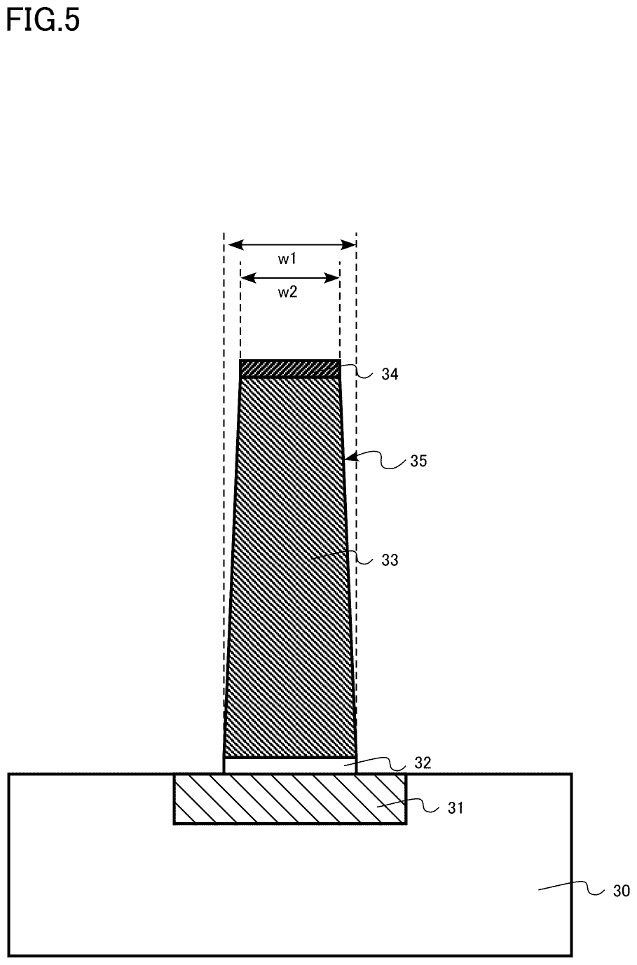

Next, the first silicon nitride film 34 and the amorphous silicon film 33 are etched to form a columnar body 35 (FIG. 5). The columnar body 35 is formed such that a first width (w1 in FIG. 5) on the side of the indium tin oxide layer 31 is larger than a second width (w2 in FIG. 5) on the opposite side of the indium tin oxide layer 31. The columnar body 35 has, for example, a cylindrical shape or a quadrangular columnar shape. The columnar body 35 is formed using, for example, a lithography method and a reactive ion etching method (RIE method).

After the amorphous silicon film 33 is etched, the first silicon oxide film 32 is continuously etched.

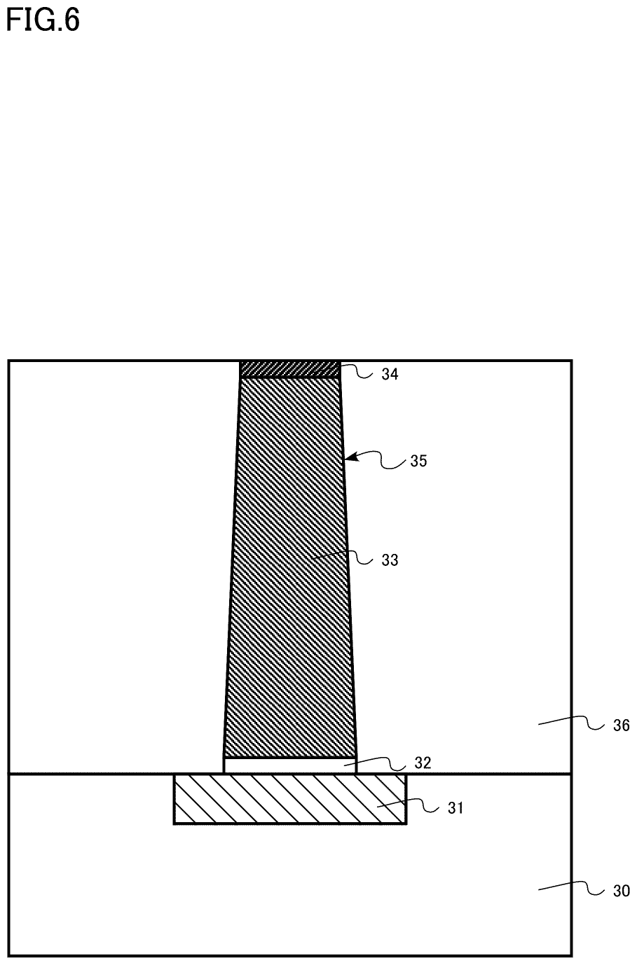

Next, the columnar body 35 is buried with a second silicon oxide film 36 (FIG. 6). The second silicon oxide film 36 is formed by, for example, deposition by a CVD method and planarization processing using a chemical mechanical polishing method (CMP method). The first silicon nitride film 34 functions as, for example, a stopper film when the CMP method is performed. The second silicon oxide film 36 is an example of the first insulating film.

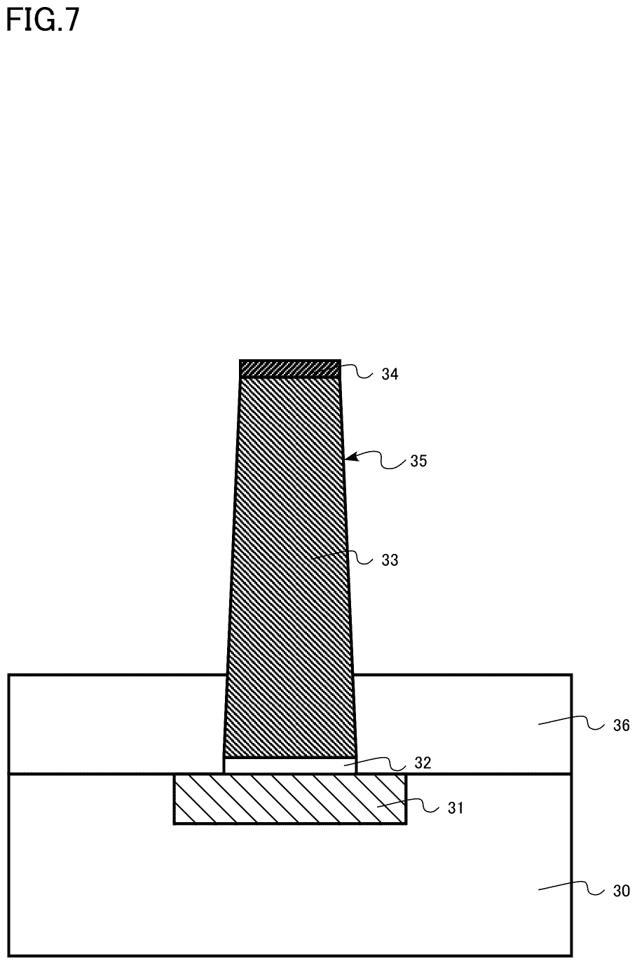

Next, a part of the second silicon oxide film 36 is etched to expose a part of the columnar body 35 (FIG. 7).

The second silicon oxide film 36 is etched using, for example, the RIE method.

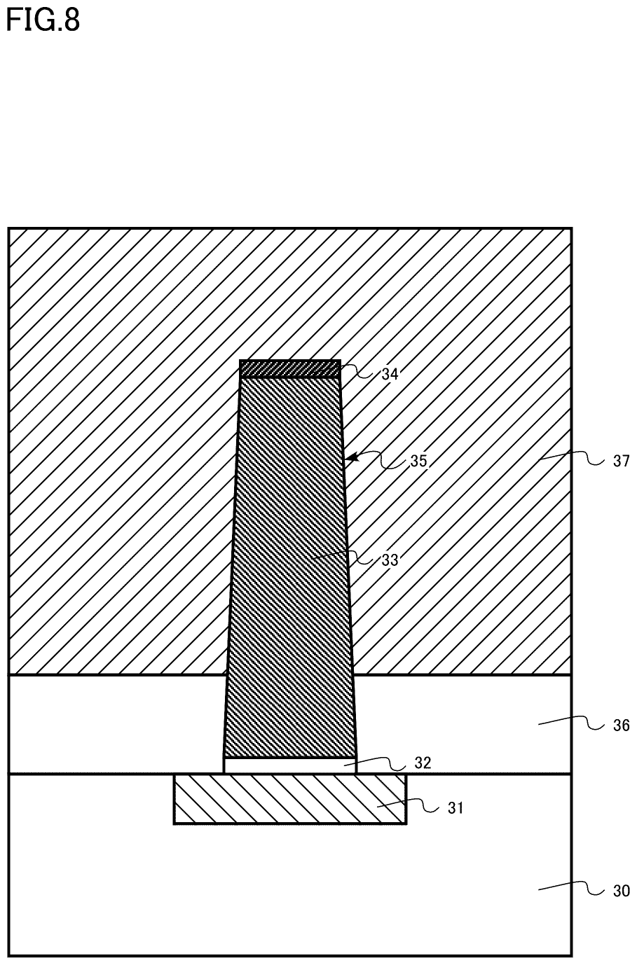

Next, the columnar body 35 is buried with a tungsten film 37 (FIG. 8). The tungsten film 37 is formed by using, for example, the CVD method. The tungsten film 37 is an example of the first metal film. A part of the tungsten film 37 finally becomes the gate electrode 18.

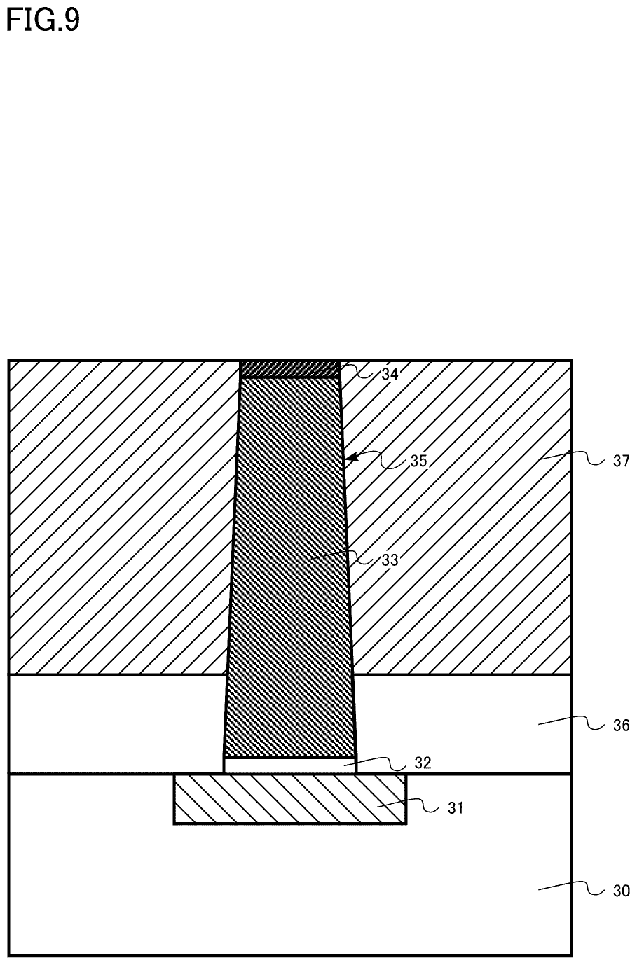

Next, a top surface of the tungsten film 37 is planarized (FIG. 9). The tungsten film 37 is planarized by the CMP method. The first silicon nitride film 34 functions as, for example, a stopper film when the CMP method is performed.

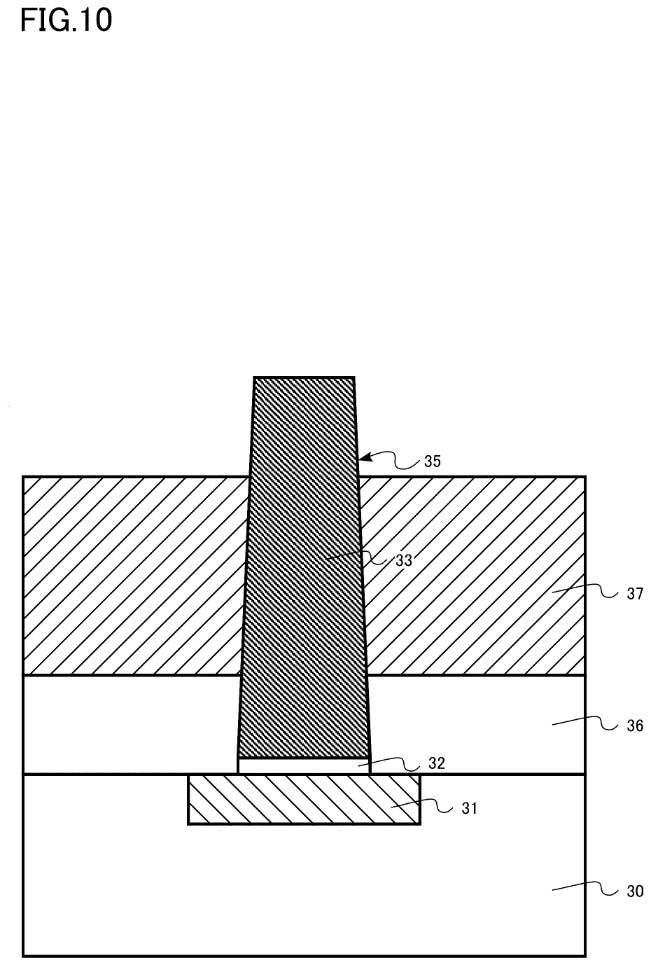

Next, a part of the tungsten film 37 is etched to expose a part of the columnar body 35 (FIG. 10). The tungsten film 37 is etched using, for example, the RIE method.

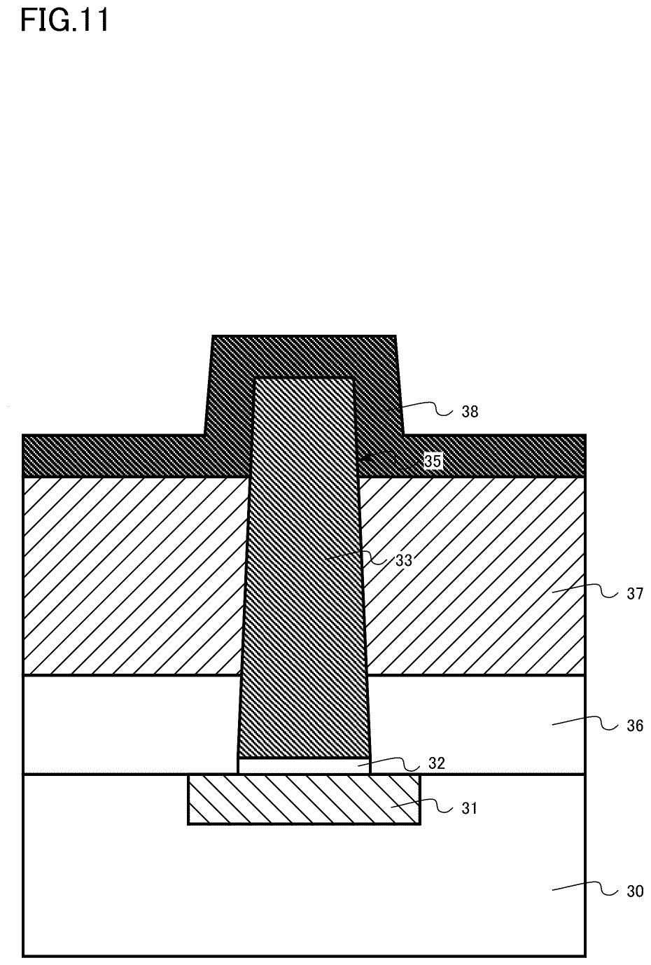

Next, the columnar body 35 is covered with a second silicon nitride film 38 (FIG. 11). The second silicon nitride film 38 is formed by using, for example, the CVD method. The second silicon nitride film 38 is an example of the second insulating film.

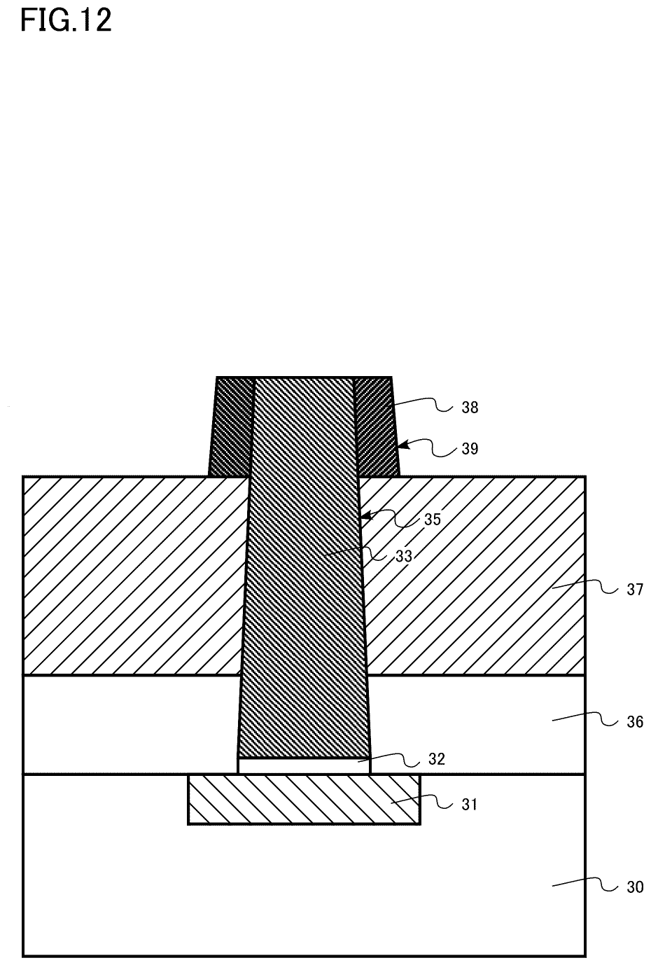

Next, the second silicon nitride film 38 is etched to form a sidewall 39 on a side surface of the columnar body 35 (FIG. 12). The sidewall 39 is formed by using, for example, the RIE method.

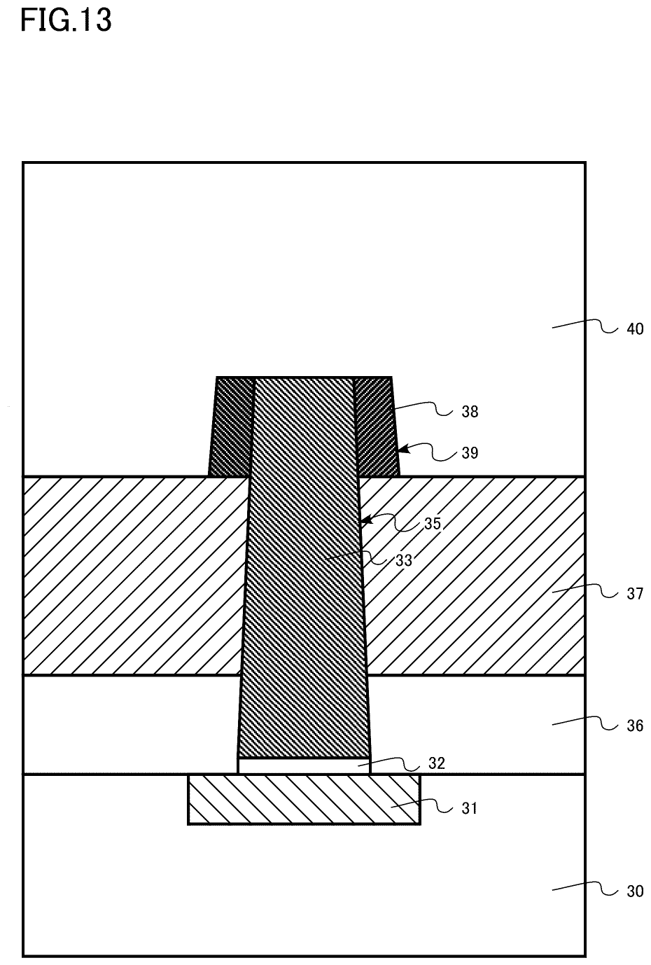

Next, the columnar body 35 and the sidewall 39 are buried with a third silicon oxide film 40 (FIG. 13). The third silicon oxide film 40 is formed by using, for example, the CVD method. The third silicon oxide film 40 is an example of the third insulating film.

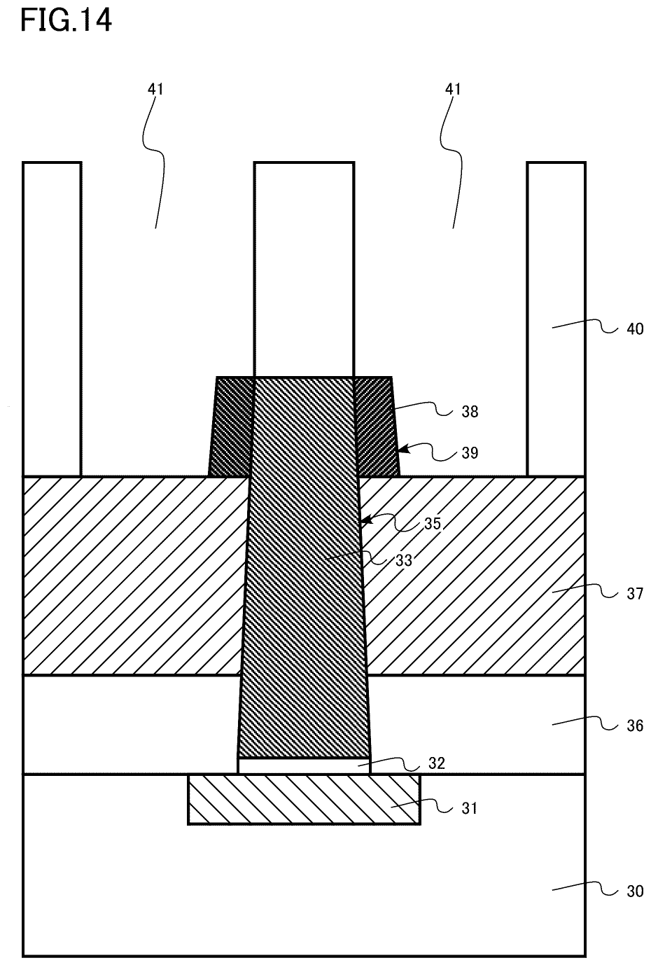

Next, the third silicon oxide film 40 is etched to form a first opening 41 through which the sidewall 39 and the tungsten film 37 are exposed (FIG. 14). The first opening 41 is formed by using the lithography method and the RIE method.

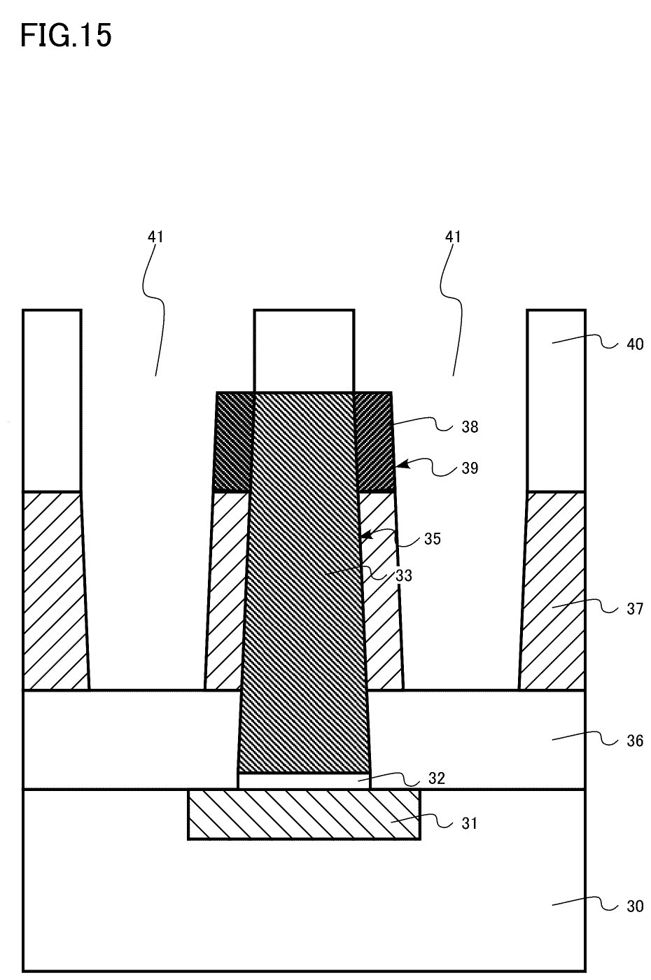

Next, the tungsten film 37 is etched using the third silicon oxide film 40 and the sidewall as a mask (FIG. 15).

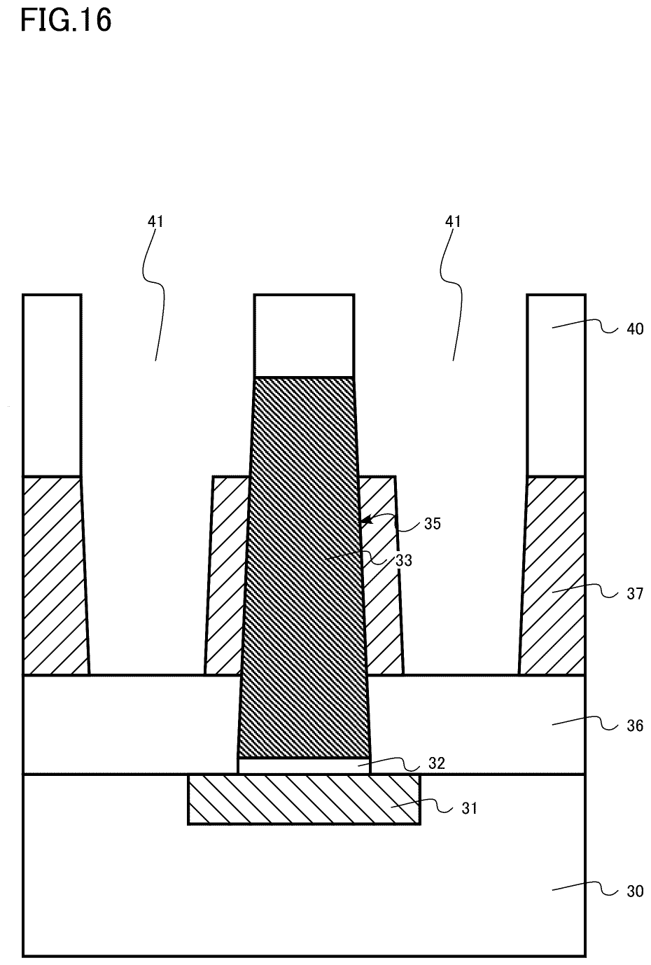

Next, the sidewall 39 is removed (FIG. 16). The sidewall 39 is removed by using, for example, a wet etching method.

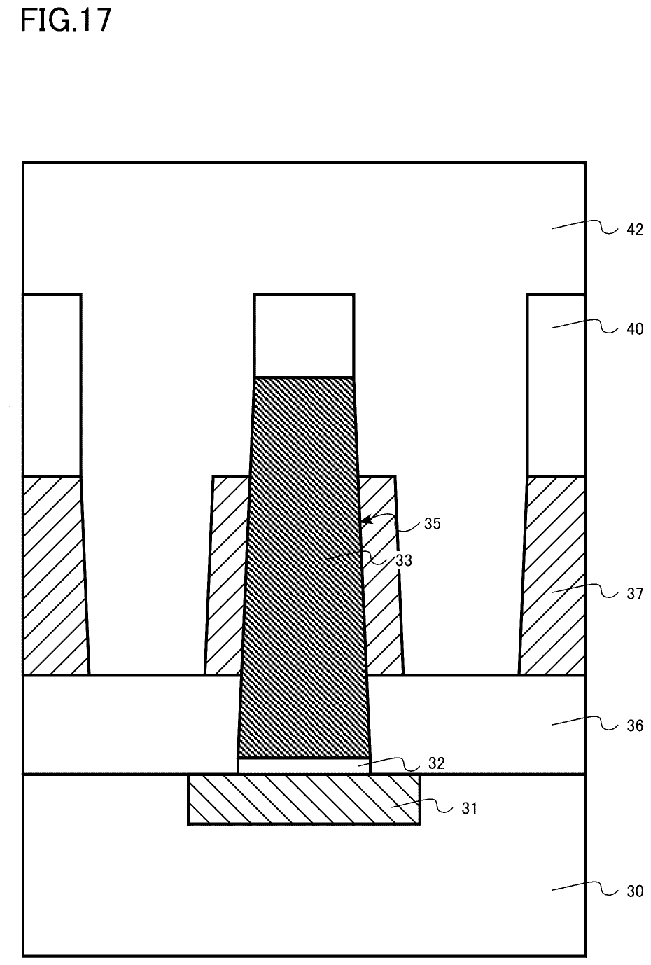

Next, the first opening 41 is buried with a fourth silicon oxide film 42 (FIG. 17). The fourth silicon oxide film 42 is formed by, for example, the CVD method. The fourth silicon oxide film 42 is an example of the fourth insulating film.

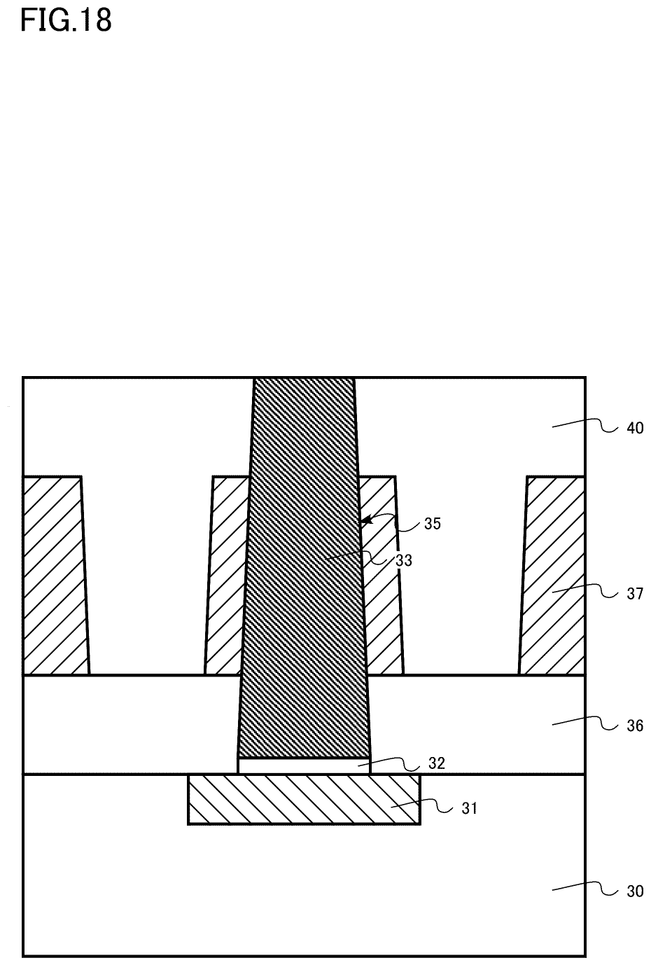

Next, the fourth silicon oxide film 42 on the columnar body 35 is removed to expose a top surface of the columnar body 35 (FIG. 18). The fourth silicon oxide film 42 is removed by using, for example, the CMP method.

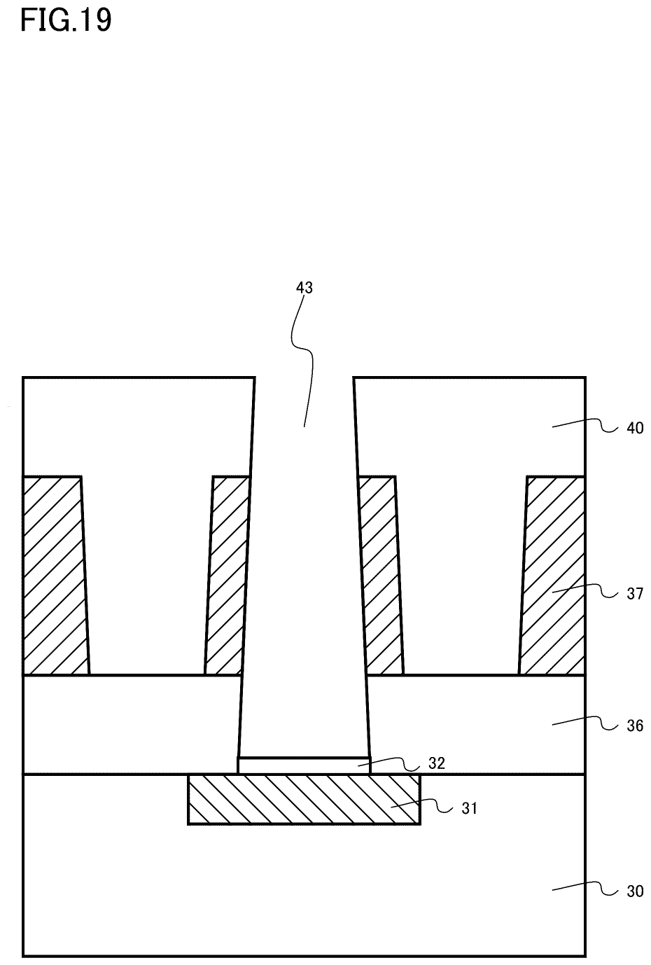

Next, the columnar body 35 is etched and removed to form a second opening 43 through which the tungsten film 37 is exposed on the side surface (FIG. 19). The etching of the amorphous silicon film 33 forming the columnar body 35 is performed by using, for example, the wet etching method. The second opening 43 has a so-called reverse tapered shape.

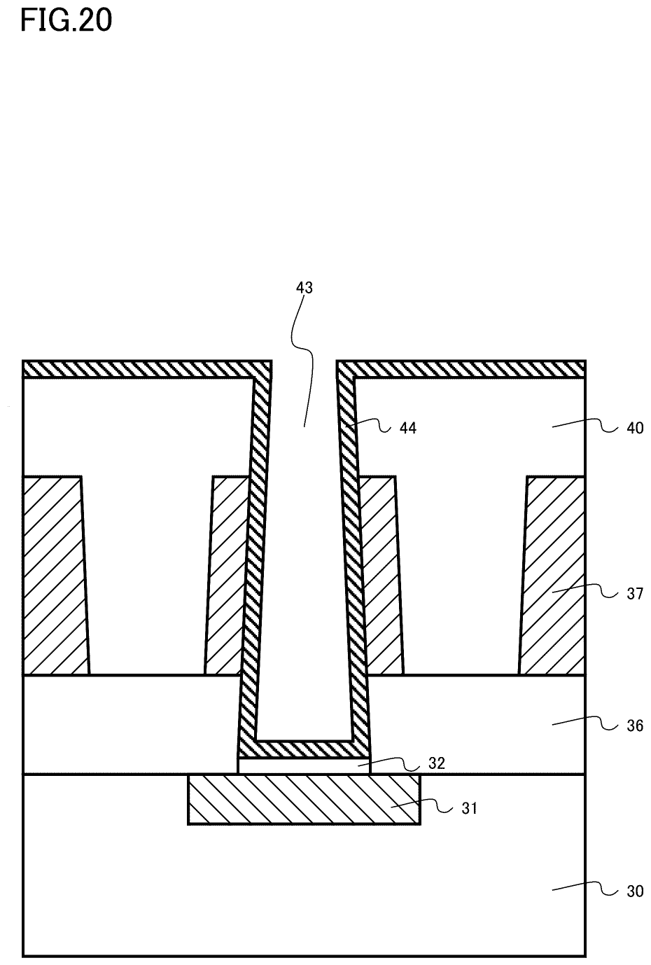

Next, a fourth silicon oxide film 44 is formed in the second opening 43 (FIG. 20). The fourth silicon oxide film 44 is formed by using, for example, the CVD method. The fourth silicon oxide film 44 is an example of the fifth insulating film. A part of the fourth silicon oxide film 44 finally becomes the gate insulating layer 20.

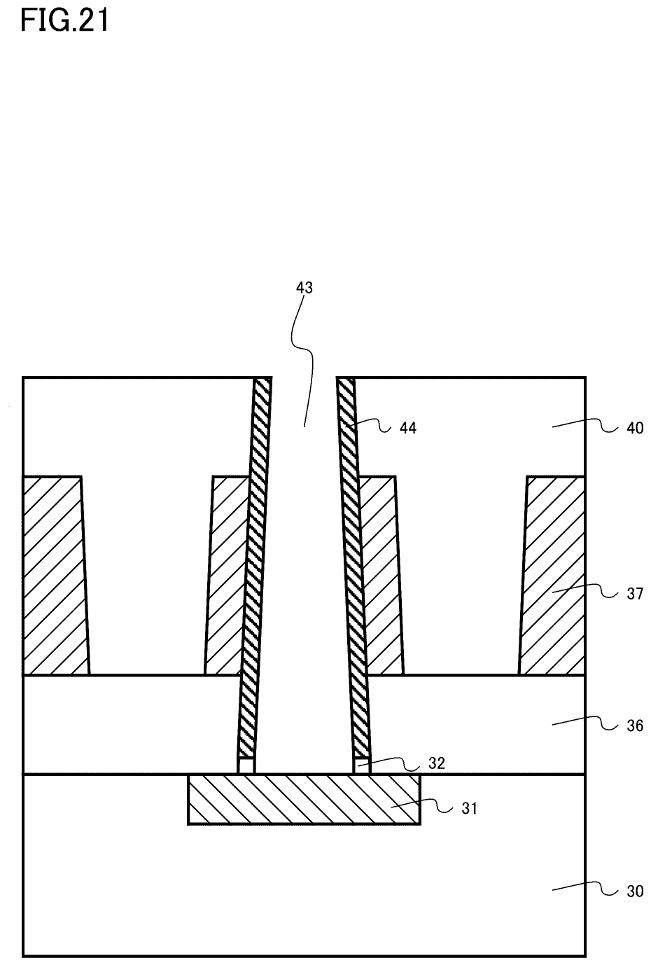

Next, the fourth silicon oxide film 44 at the bottom of the second opening 43 is etched and removed (FIG. 21). At this time, a part of the first silicon oxide film 32 is also etched to expose the surface of the indium tin oxide layer 31. The etching of the fourth silicon oxide film 44 is performed by using the RIE method.

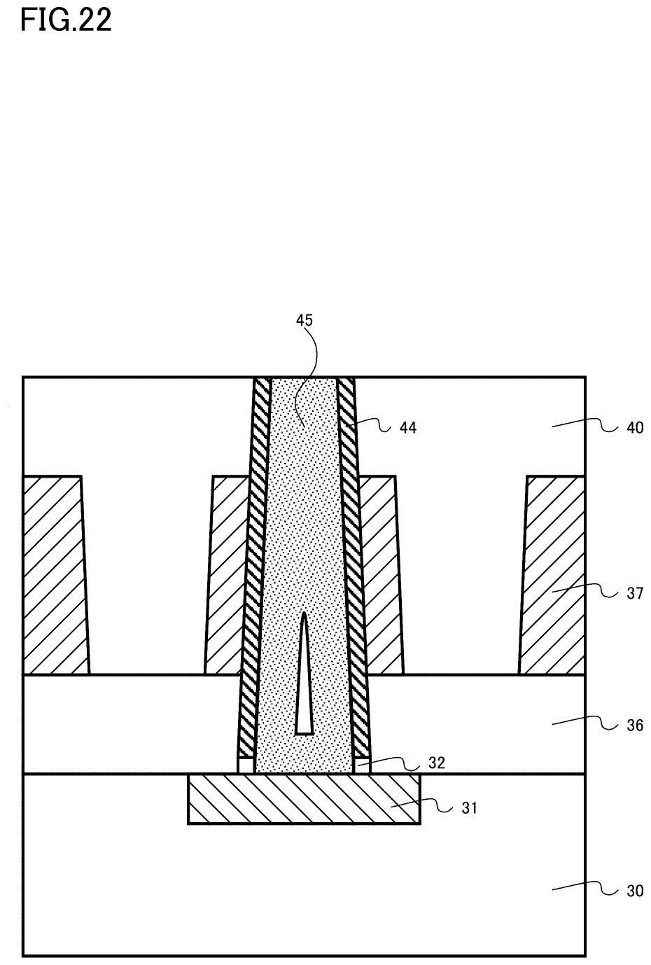

Next, the second opening 43 is buried with an indium gallium zinc oxide film 45 (FIG. 22). The indium gallium zinc oxide film 45 is formed by using, for example, the CVD method and then planarized by using the CMP method. Since the second opening 43 has a reverse tapered shape, a void is formed in the indium gallium zinc oxide film 45 with which the second opening 43 has been buried.

The indium gallium zinc oxide film 45 finally becomes the oxide semiconductor layer 16. The indium gallium zinc oxide film 45 is an example of the semiconductor film.

Then, the upper electrode 14 of the indium tin oxide layer is formed using known process technology.

The transistor 100 illustrated in FIGS. 1 and 2 is manufactured by the above manufacturing method.

In the example of the above manufacturing method, the amorphous silicon film has been used as the first film. However, for example, a carbon film can also be used as the first film.

Next, functions and effects of the semiconductor device and the method for manufacturing the semiconductor device according to the first embodiment will be described.

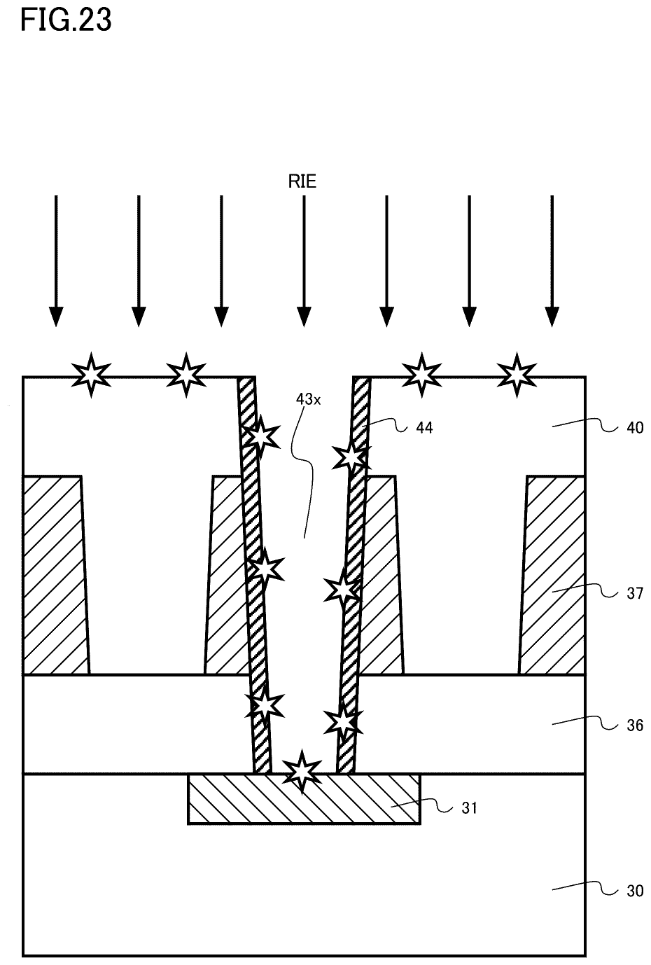

FIG. 23 is an explanatory diagram of functions and effects of the semiconductor device and the method for manufacturing the semiconductor device according to the first embodiment. FIG. 23 is a schematic cross-sectional view illustrating an example of a method for manufacturing a semiconductor device according to a comparative example. FIG. 23 is a diagram corresponding to FIG. 21 illustrating the manufacturing method according to the first embodiment.

The method for manufacturing the semiconductor device according to the comparative example is different from the method for manufacturing the semiconductor device according to the first embodiment in that an opening 43x corresponding to the second opening 43 in the method for manufacturing the semiconductor device according to the first embodiment has a forward tapered shape.

In the process illustrated in FIG. 23, the fourth silicon oxide film 44 at the bottom of the second opening 43 is etched and removed. At this time, the fourth silicon oxide film 44 is etched by using the RIE method.

The RIE method is anisotropic etching using ion impact in a direction perpendicular to a substrate. At this time, the surface of the fourth silicon oxide film 44 formed on a side surface of the opening 43x is directly exposed to ion impact. Therefore, processing damage remains in the fourth silicon oxide film 44.

The fourth silicon oxide film 44 finally becomes the gate insulating layer. Since processing damage remains in the gate insulating layer, the reliability of the gate insulating layer decreases. Specifically, for example, time dependent dielectric breakdown characteristics (TDDB characteristics) of the gate insulating layer are degraded.

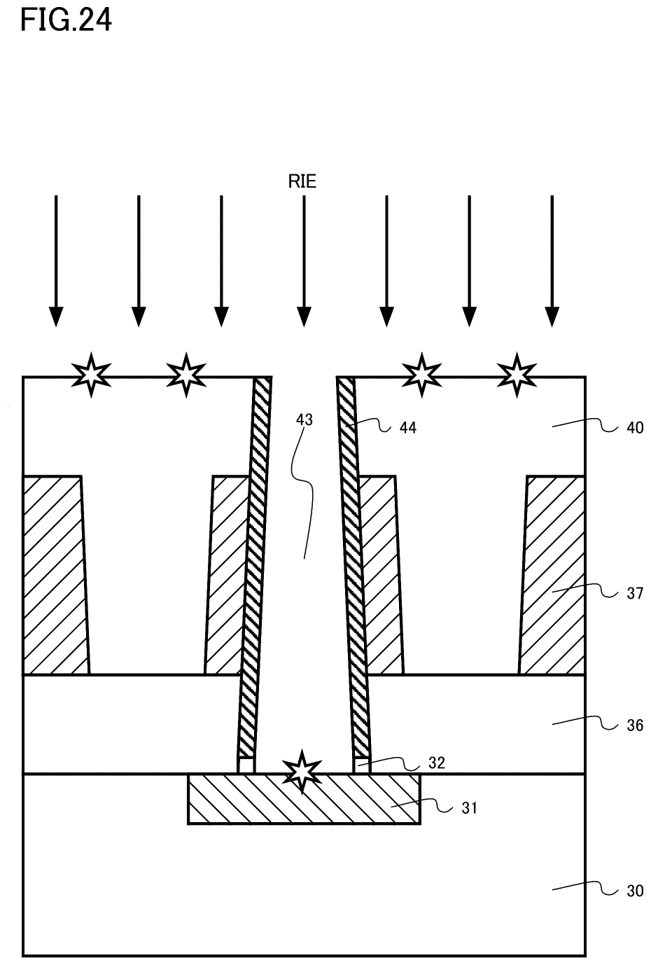

FIG. 24 is an explanatory diagram of functions and effects of the semiconductor device and the method for manufacturing the semiconductor device according to the first embodiment. FIG. 24 is a diagram corresponding to FIG. 21 illustrating the manufacturing method according to the first embodiment.

The second opening 43 in the method for manufacturing the semiconductor device according to the first embodiment has a reverse tapered shape. For this reason, as illustrated in FIG. 24, when the fourth silicon oxide film 44 is etched using the RIE method, the surface of the fourth silicon oxide film 44 formed on the side surface of the second opening 43 is not directly exposed to ion impact. Therefore, processing damage does not remain in the fourth silicon oxide film 44.

Therefore, the reliability of the gate insulating layer 20 is improved as compared with the method for manufacturing the semiconductor device according to the comparative example. As a result, the transistor 100 with improved reliability can be realized.

As described above, according to the semiconductor device and the method for manufacturing the semiconductor device according to the first embodiment, a semiconductor device having excellent transistor characteristics can be realized.

### (Modification)

A semiconductor device according to a modification of the first embodiment is different from the semiconductor device according to the first embodiment in that a first thickness in a first direction of a portion of a first electrode in contact with an oxide semiconductor layer is smaller than a second thickness in the first direction of a portion of the first electrode closest to a gate insulating layer in the first direction.

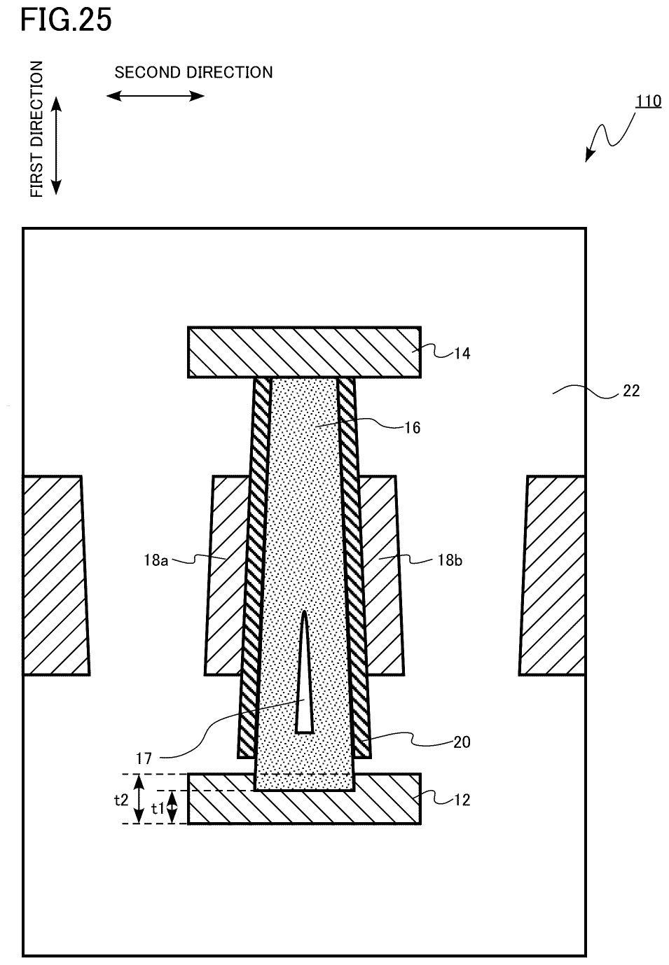

FIG. 25 is a schematic cross-sectional view of the semiconductor device according to the modification of the first embodiment. FIG. 25 is a diagram corresponding to FIG. 2 illustrating the first embodiment.

The semiconductor device according to the modification of the first embodiment is a transistor 110.

In the transistor 110, a first thickness (t1 in FIG. 25) in the first direction of a portion of the lower electrode 12 in contact with the oxide semiconductor layer 16 is smaller than a second thickness (t2 in FIG. 25) in the first direction of a portion of the lower electrode 12 closest to the gate insulating layer 20 in the first direction. The first thickness t1 is, for example, 0.5 times or more and 0.95 times or less the second thickness t2.

The lower electrode 12 of the transistor 110 has a recess on the surface on the oxide semiconductor layer 16 side, and the oxide semiconductor layer 16 is provided in the recess.

The transistor 110 can be manufactured, for example, by etching the surface of the indium tin oxide layer 31 when the fourth silicon oxide film 44 and the first silicon oxide film 32 at the bottom of the second opening 43 are etched and removed in the process of FIG. 21 illustrating the method for manufacturing the semiconductor device of the first embodiment.

In the transistor 110, a contact area between the oxide semiconductor layer 16 and the lower electrode 12 increases. Therefore, contact resistance between the oxide semiconductor layer 16 and the lower electrode 12 decreases. As a result, a transistor that reduces on-resistance can be realized.

According to the semiconductor device and the method for manufacturing the semiconductor device according to the modification of the first embodiment, a transistor with improved reliability can be realized similarly to the first embodiment. In addition, a transistor that reduces the on-resistance can be realized.

As described above, according to the semiconductor device and the method for manufacturing the semiconductor device of each of the first embodiment and the modification, a semiconductor device having excellent transistor characteristics can be realized.

### Second Embodiment

A method for manufacturing a semiconductor device according to a second embodiment is different from the method for manufacturing the semiconductor device according to the first embodiment in that, before etching a first film, a second film having a chemical composition different from a chemical composition of the first film is further formed on the first film, before etching the first film, the second film is etched to leave the second film on a columnar body, the second film is also buried when the columnar body and a sidewall are buried with a third insulating film, and after removing a fourth insulating film on the columnar body, the second film is etched and removed before exposing the columnar body. Hereinafter, description of contents overlapping with those of the first embodiment may be partially omitted.

An example of the method for manufacturing the semiconductor device according to the second embodiment will be described.

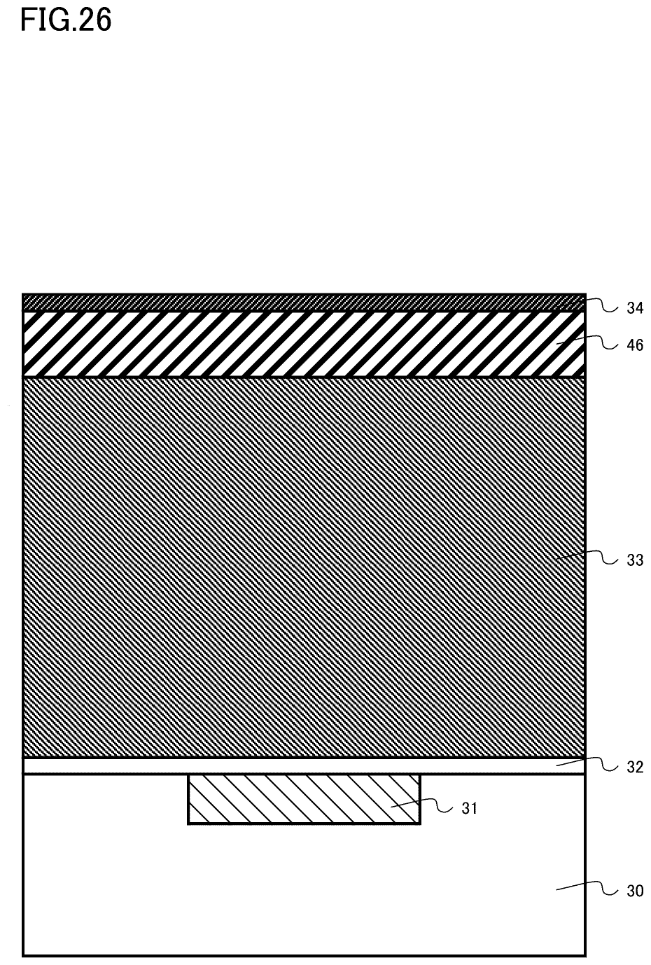

FIGS. 26 to 30 are schematic cross-sectional views illustrating an example of the method for manufacturing the semiconductor device according to the second embodiment. Each of FIGS. 26 to 30 illustrates a cross section corresponding to FIG. 1 illustrating the first embodiment. FIGS. 26 to 30 are diagrams illustrating another example of the method for manufacturing the transistor 100 according to the first embodiment.

First, a first silicon oxide film 32, an amorphous silicon film 33, a boron carbide film 46, and a first silicon nitride film 34 are formed on an indium tin oxide layer 31 formed in a silicon nitride layer 30 (FIG. 26). The first silicon oxide film 32, the amorphous silicon film 33, the boron carbide film 46, and the first silicon nitride film 34 are formed by using, for example, a CVD method.

A chemical composition of the boron carbide film 46 is different from a chemical composition of the amorphous silicon film 33. The boron carbide film 46 is an example of the second film.

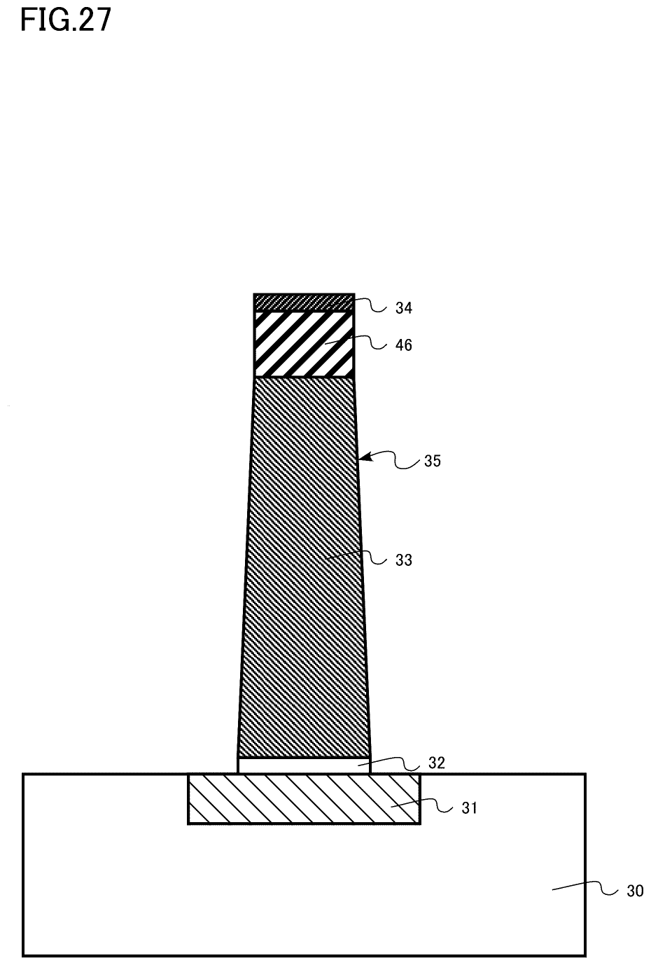

Next, the first silicon nitride film 34, the boron carbide film 46, the amorphous silicon film 33, and the first silicon oxide film 32 are etched to form a columnar body 35 (FIG. 27). The boron carbide film 46 is left on the columnar body 35.

Then, processes similar to those in FIGS. 6 to 12 illustrating the method for manufacturing the semiconductor device of the first embodiment are performed.

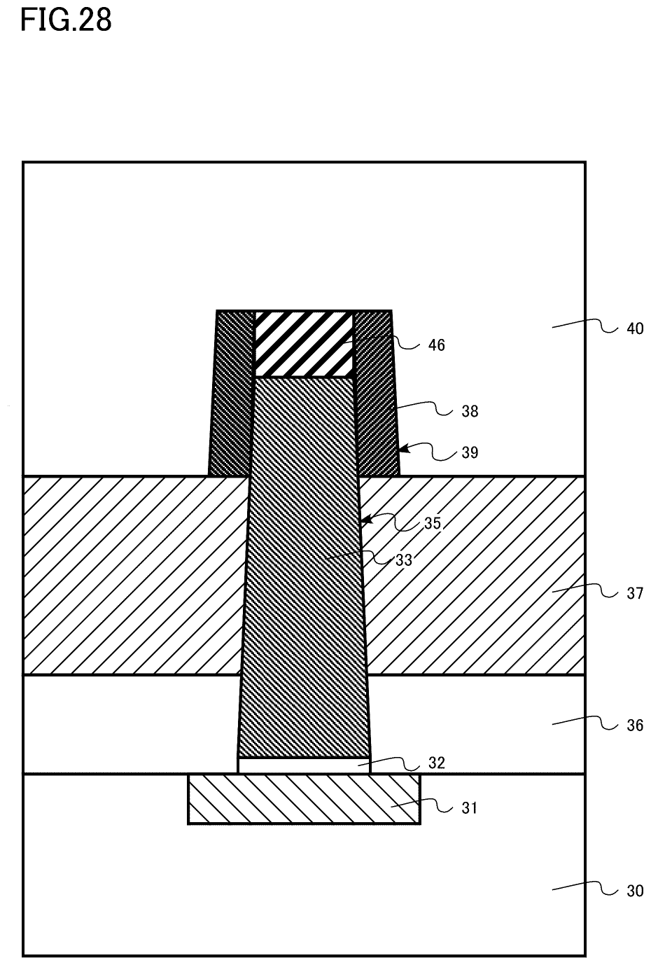

Next, the columnar body 35, the boron carbide film 46, and a sidewall 39 are buried with a third silicon oxide film 40 (FIG. 28). The third silicon oxide film 40 is formed by using, for example, the CVD method. The third silicon oxide film 40 is an example of the third insulating film.

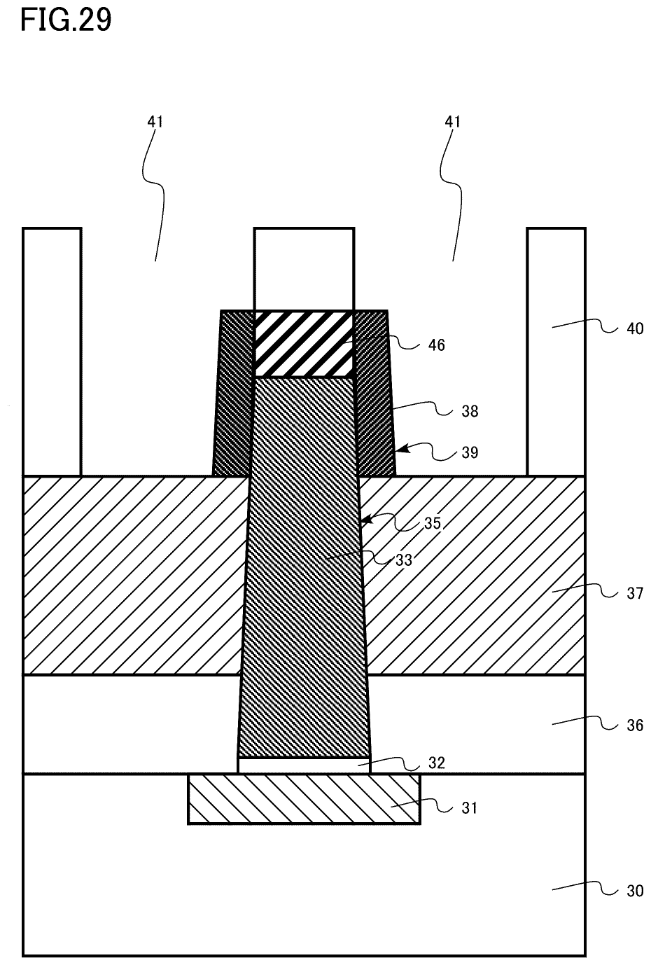

Next, the third silicon oxide film 40 is etched to form a first opening 41 through which the sidewall 39 and a tungsten film 37 are exposed (FIG. 29). The first opening 41 is formed by using the lithography method and the RIE method.

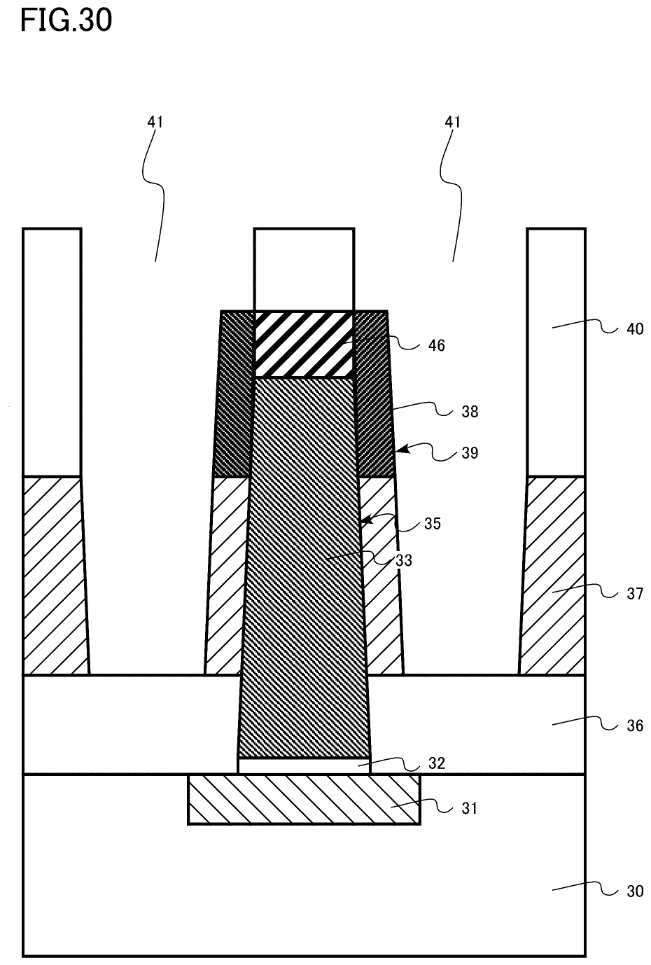

Next, the tungsten film 37 is etched using the third silicon oxide film 40 and the sidewall 39 as a mask (FIG. 30).

Then, processes similar to those in FIGS. 16 to 22 illustrating the method for manufacturing the semiconductor device of the first embodiment are performed. Further, an upper electrode 14 of the indium tin oxide layer is formed.

After a fourth silicon oxide film 42 on the columnar body 35 is removed, the boron carbide film 46 is etched and removed before the columnar body 35 is exposed. Then, the amorphous silicon columnar body 35 is removed to form a second opening 43.

The transistor 100 illustrated in FIGS. 1 and 2 is manufactured by the above manufacturing method.

In an example of the above manufacturing method, a boron carbide film is used as the second film, but for example, a boron nitride film can also be used as the first film.

Next, functions and effects of the method for manufacturing the semiconductor device according to the second embodiment will be described.

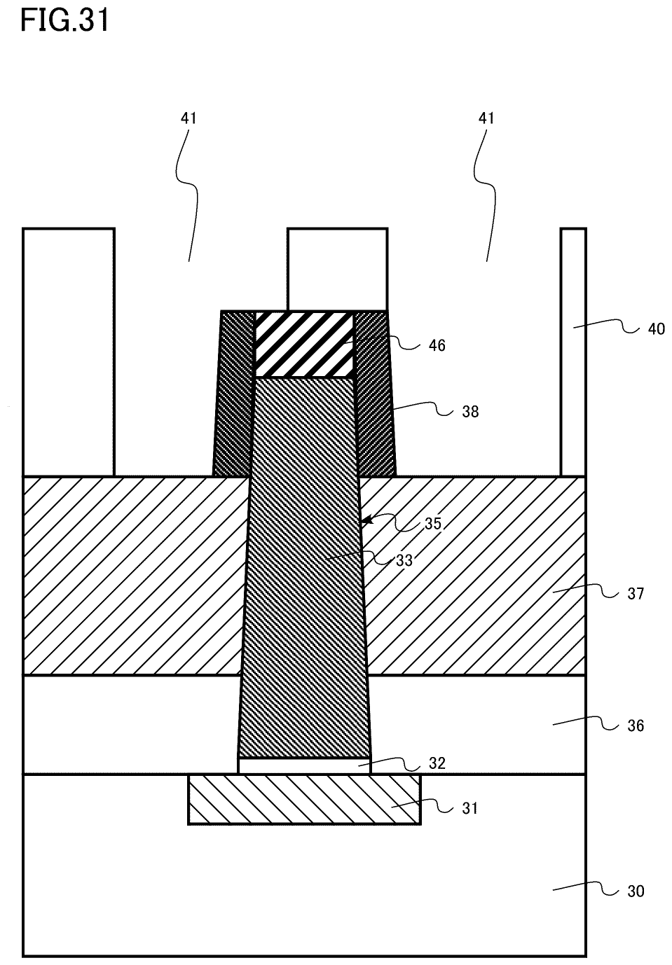

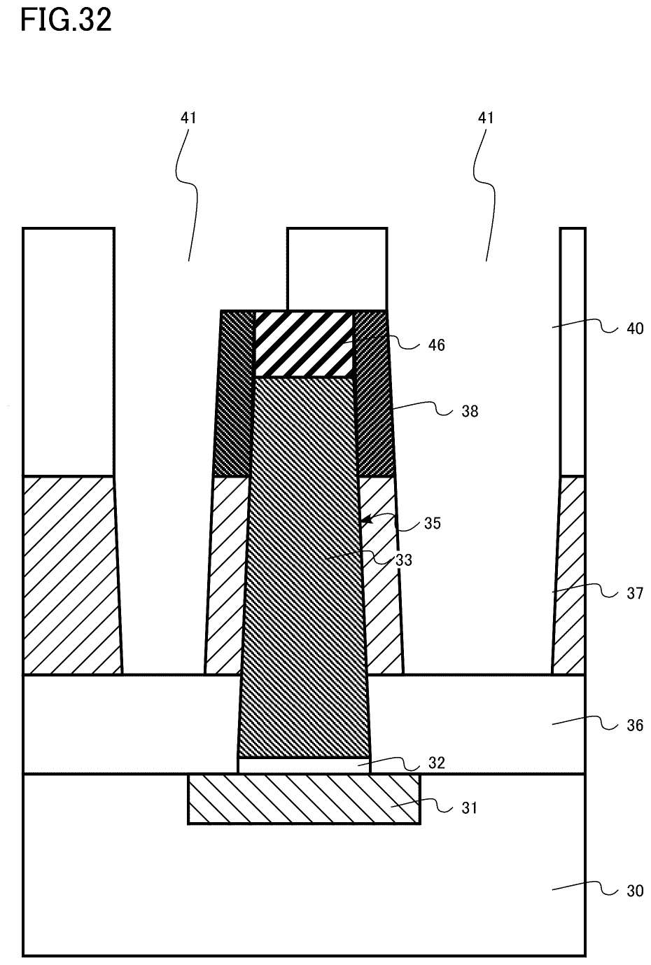

FIGS. 31 and 32 are explanatory diagrams of functions and effects of the method for manufacturing the semiconductor device according to the second embodiment. FIGS. 31 and 32 are diagrams corresponding to FIGS. 29 and 30 illustrating the manufacturing method according to the second embodiment.

FIGS. 31 and 32 illustrate a case where misalignment occurs in a left-right direction in the first opening 41 formed in the third silicon oxide film 40 due to misalignment in the lithography method. As illustrated in FIG. 31, for example, the first opening 41 overlaps an upper portion of the columnar body 35 due to misalignment. That is, the upper portion of the columnar body 35 is exposed.

In this case, as illustrated in FIG. 32, since the boron carbide film 46 having a high etching selection ratio to the etching of the tungsten film 37 is on the columnar body 35, the amorphous silicon film 33 forming the columnar body 35 is suppressed from being etched. In other words, in a case where the boron carbide film 46 is not provided, if the first opening 41 overlaps the upper portion of the columnar body 35 due to misalignment, the amorphous silicon film 33 is etched, and a manufacturing defect may occur.

According to the method for manufacturing the semiconductor device of the second embodiment, for example, a manufacturing defect due to misalignment is suppressed, and a manufacturing yield of the semiconductor device is improved.

As described above, according to the method for manufacturing the semiconductor device of the second embodiment, a transistor with improved reliability can be realized similarly to the first embodiment. Further, a transistor with an improved manufacturing yield can be realized. According to the method for manufacturing the semiconductor device of the second embodiment, a semiconductor device having excellent transistor characteristics can be realized.

### Third Embodiment

A semiconductor device according to a third embodiment is different from the semiconductor device according to the first embodiment in that an oxide semiconductor layer includes a first region partially in contact with a first electrode, and a first length of the first region in a second direction is larger than a second length of the first electrode in the second direction. Hereinafter, description of contents overlapping with those of the first embodiment may be partially omitted.

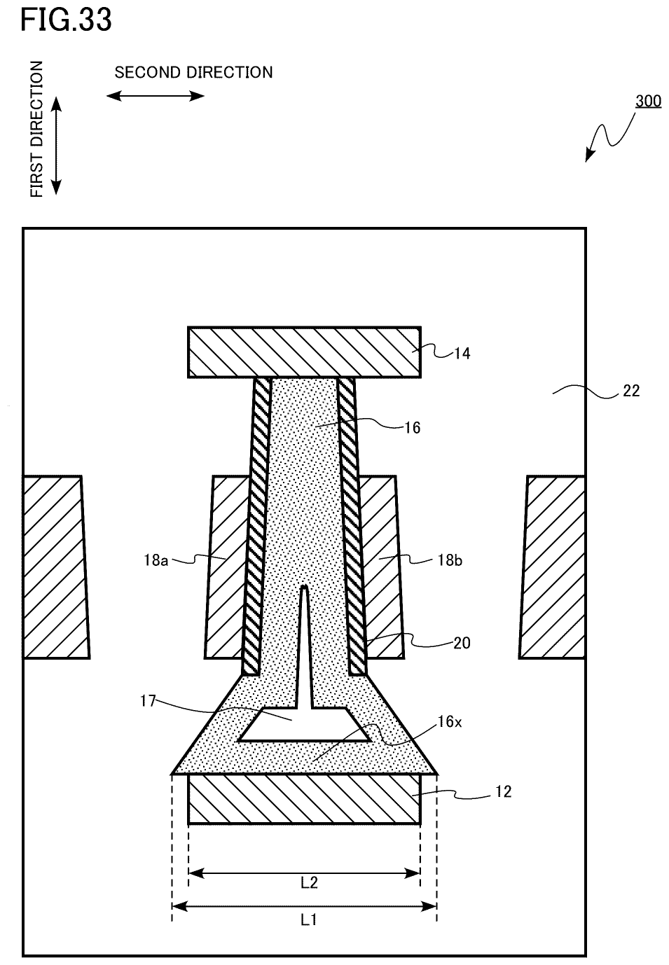

FIG. 33 is a schematic cross-sectional view of the semiconductor device according to the third embodiment. FIG. 33 is a diagram corresponding to FIG. 2 illustrating the first embodiment.

The semiconductor device according to the third embodiment is a transistor 300.

An oxide semiconductor layer 16 of the transistor 300 includes a first region 16x. A part of the first region 16x is in contact with a lower electrode 12. A first length (L1 in FIG. 33) at the bottom of the first region 16x in the second direction is larger than a second length (L2 in FIG. 33) of the lower electrode 12 in a first direction. The first length L1 is, for example, 1.1 times or more and 2 times or less the second length L2.

Next, an example of a method for manufacturing the semiconductor device according to the third embodiment will be described.

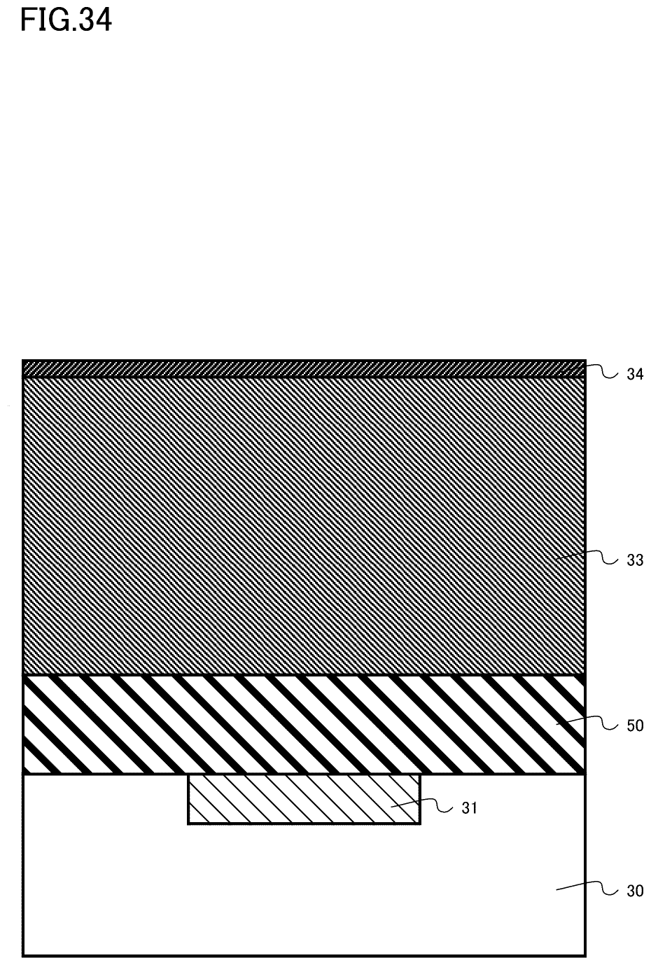

FIGS. 34 to 53 are schematic cross-sectional views illustrating an example of the method for manufacturing the semiconductor device according to the third embodiment. Each of FIGS. 34 to 53 illustrates a cross section corresponding to FIG. 1. FIGS. 34 to 53 are diagrams illustrating an example of a method for manufacturing the transistor 300.

Hereinafter, a case where the lower electrode 12 of the transistor 300 is an indium tin oxide layer, an upper electrode 14 is an indium tin oxide layer, an oxide semiconductor layer 16 is an indium gallium zinc oxide layer, a gate electrode 18 is a tungsten layer, a gate insulating layer 20 is a silicon oxide layer, and an interlayer insulating layer 22 is a silicon nitride layer and a silicon oxide layer will be described as an example.

As an example, the method for manufacturing the semiconductor device according to the third embodiment includes: forming a first film on a first conductive layer; etching the first film to form a columnar body in which a first width on a side of the first conductive layer is larger than a second width on an opposite side of the first conductive layer; burying the columnar body with a first insulating film; etching a part of the first insulating film to expose a part of the columnar body; burying the columnar body with a first metal film; etching a part of the first metal film to expose a part of the columnar body; covering the columnar body with a second insulating film; etching the second insulating film to form a sidewall on a side surface of the columnar body; burying the columnar body and the sidewall with a third insulating film; etching the third insulating film to form a first opening through which the sidewall and the first metal film are exposed; etching the first metal film using the third insulating film and the sidewall as a mask; burying the first opening with a fourth insulating film; removing the fourth insulating film on the columnar body; exposing the columnar body; etching and removing the columnar body to form a second opening through which the first metal film is exposed on a side surface; forming a fifth insulating film in the second opening; etching and removing the fifth insulating film at a bottom of the second opening; and burying the second opening with a semiconductor film. Further, before forming the first film, a third film having a chemical composition different from a chemical composition of the first film is further formed on the first conductive layer, after etching the first film, the third film is etched such that a third width of the third film on a side of the first conductive layer is larger than the first width, and after etching the fifth insulating film at the bottom, the third film is further etched to expose the first conductive layer.

First, an aluminum oxide film 50, an amorphous silicon film 33, and a first silicon nitride film 34 are formed on an indium tin oxide layer 31 formed in a silicon nitride layer 30 (FIG. 34). The aluminum oxide film 50, the amorphous silicon film 33, and the first silicon nitride film 34 are formed by using, for example, a CVD method.

The silicon nitride layer 30 finally becomes the interlayer insulating layer 22. The indium tin oxide layer 31 finally becomes the lower electrode 12. The indium tin oxide layer 31 is an example of the first conductive layer. A chemical composition of the aluminum oxide film 50 is different from a chemical composition of the amorphous silicon film 33. The aluminum oxide film 50 is an example of the third film. The amorphous silicon film 33 is an example of the first film.

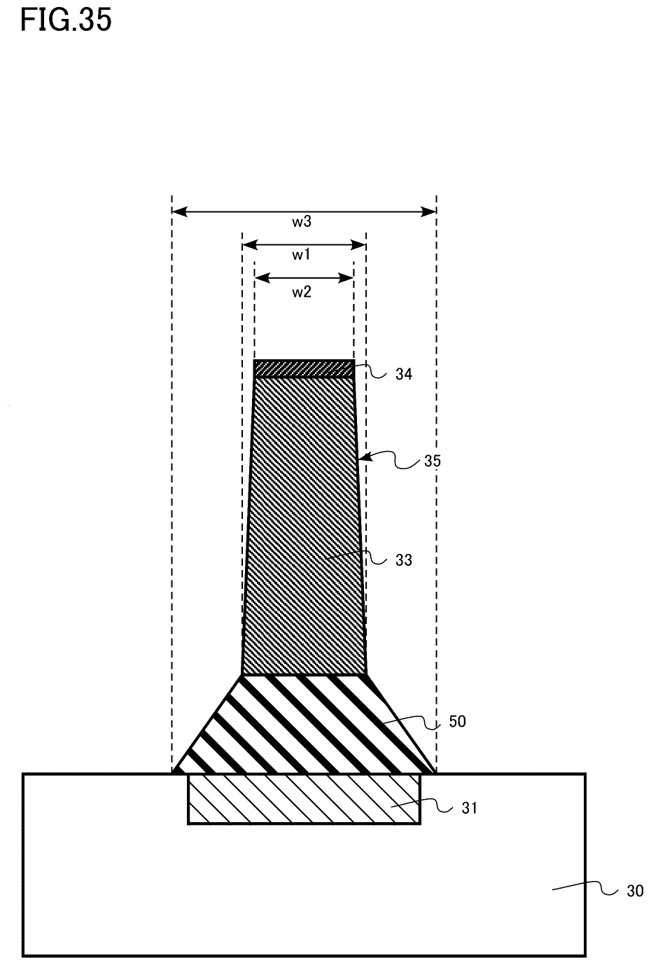

Next, the first silicon nitride film 34 and the amorphous silicon film 33 are etched to form a columnar body 35 (FIG. 35). The columnar body 35 is formed such that a first width (w1 in FIG. 35) on the side of the indium tin oxide layer 31 is larger than a second width (w2 in FIG. 35) on the opposite side of the indium tin oxide layer 31. The columnar body 35 has, for example, a cylindrical shape or a quadrangular columnar shape. The columnar body 35 is formed by using, for example, a lithography method and a RIE method.

Further, after the amorphous silicon film 33 is etched, the aluminum oxide film 50 is etched such that a third width (w3 in FIG. 35) of the aluminum oxide film 50 on the indium tin oxide layer 31 side is larger than the first width (w1 in FIG. 35). So-called taper etching is performed.

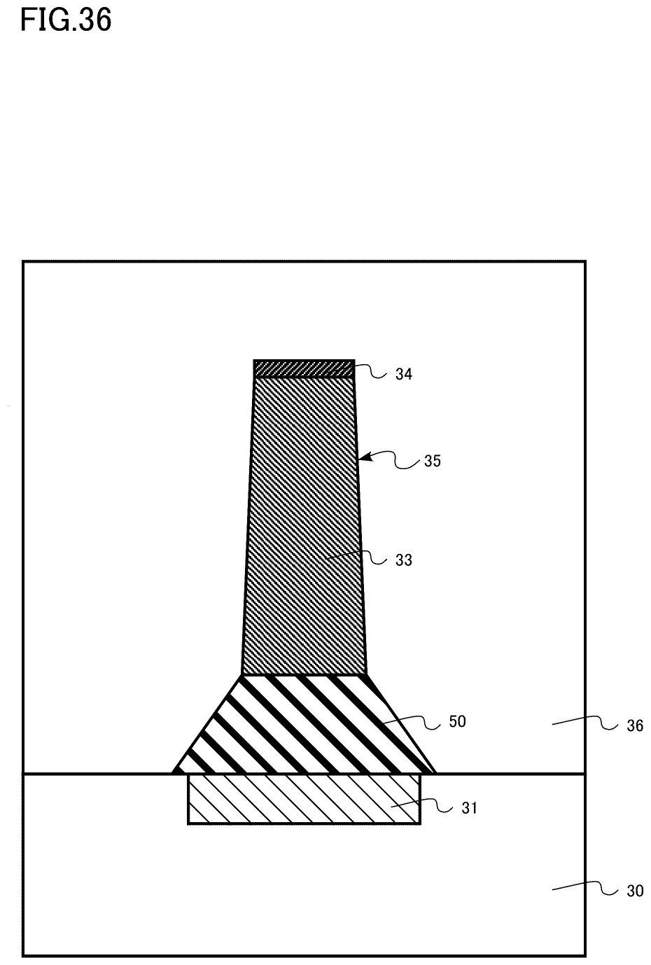

Next, the columnar body 35 is buried with a second silicon oxide film 36 (FIG. 36). The second silicon oxide film 36 is formed by, for example, deposition by a CVD method and planarization processing using a CMP method. The first silicon nitride film 34 functions as, for example, a stopper film when the CMP method is performed. The second silicon oxide film 36 is an example of the first insulating film.

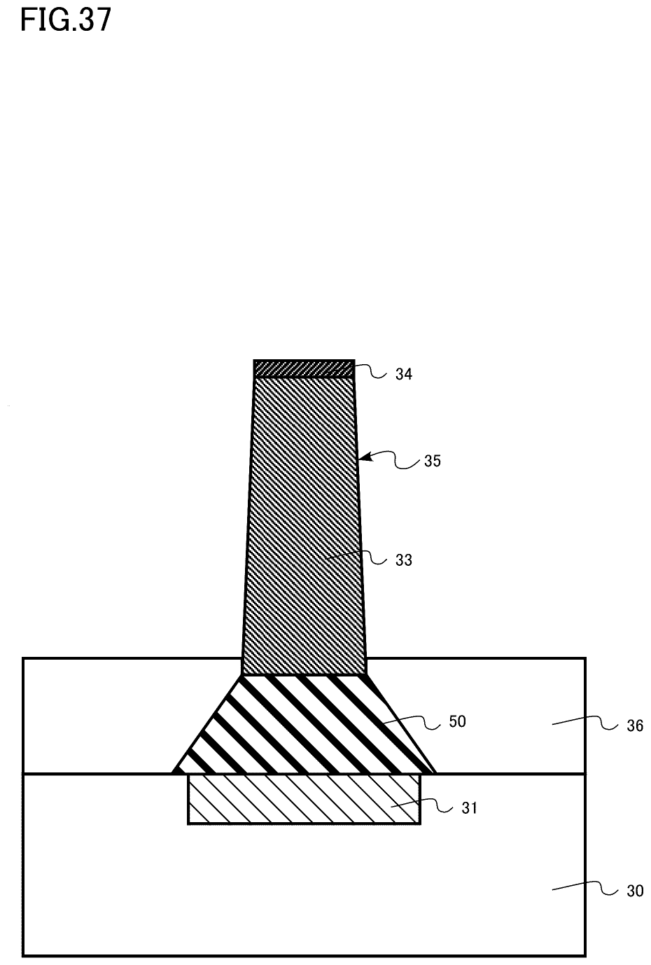

Next, a part of the second silicon oxide film 36 is etched to expose the columnar body 35 (FIG. 37). The second silicon oxide film 36 is etched by using, for example, the RIE method.

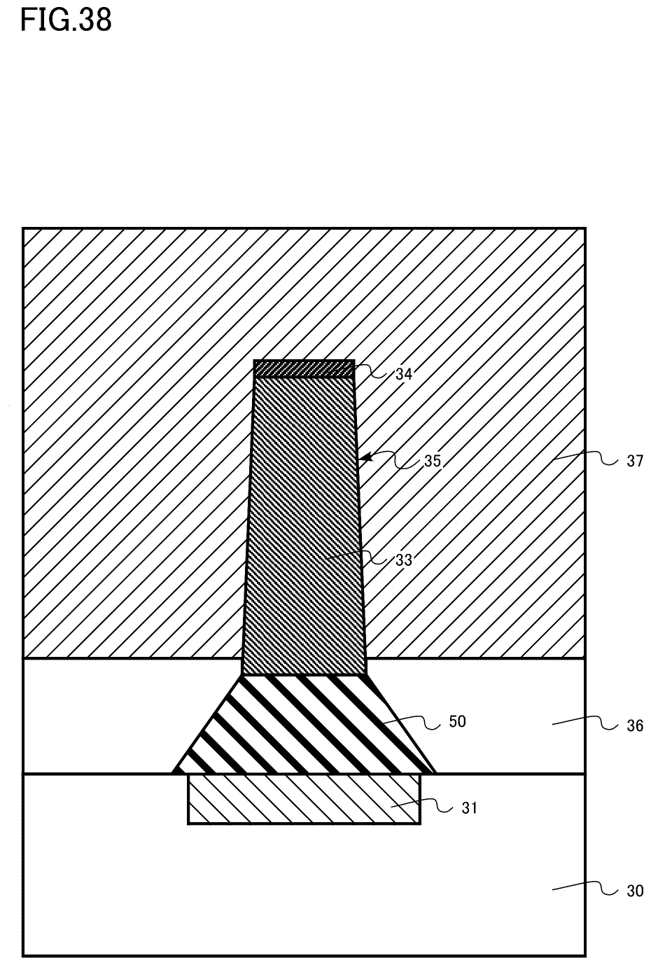

Next, the columnar body 35 is buried with a tungsten film 37 (FIG. 38). The tungsten film 37 is formed by using, for example, the CVD method. The tungsten film 37 is an example of the first metal film. A part of the tungsten film 37 finally becomes the gate electrode 18.

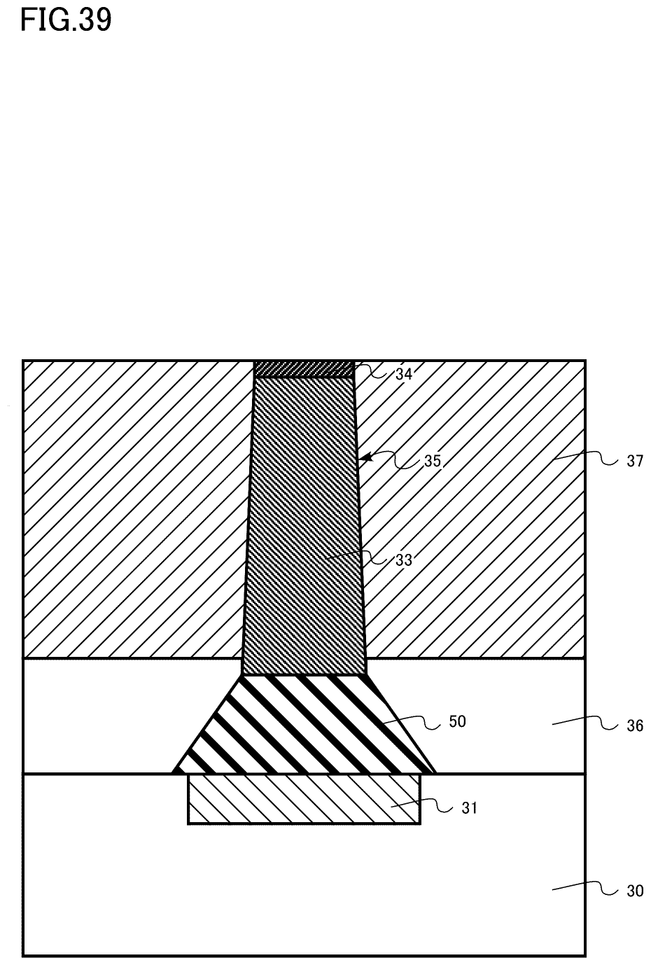

Next, a top surface of the tungsten film 37 is planarized (FIG. 39). The tungsten film 37 is planarized by the CMP method. The first silicon nitride film 34 functions as, for example, a stopper film when the CMP method is performed.

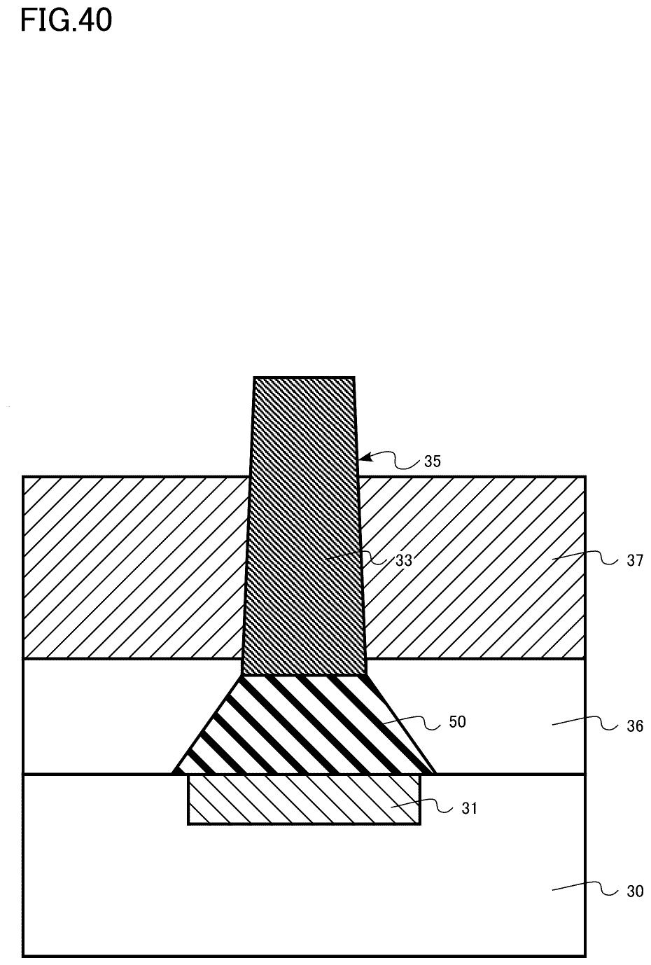

Next, a part of the tungsten film 37 is etched to expose a part of the columnar body 35 (FIG. 40). The tungsten film 37 is etched using, for example, the RIE method.

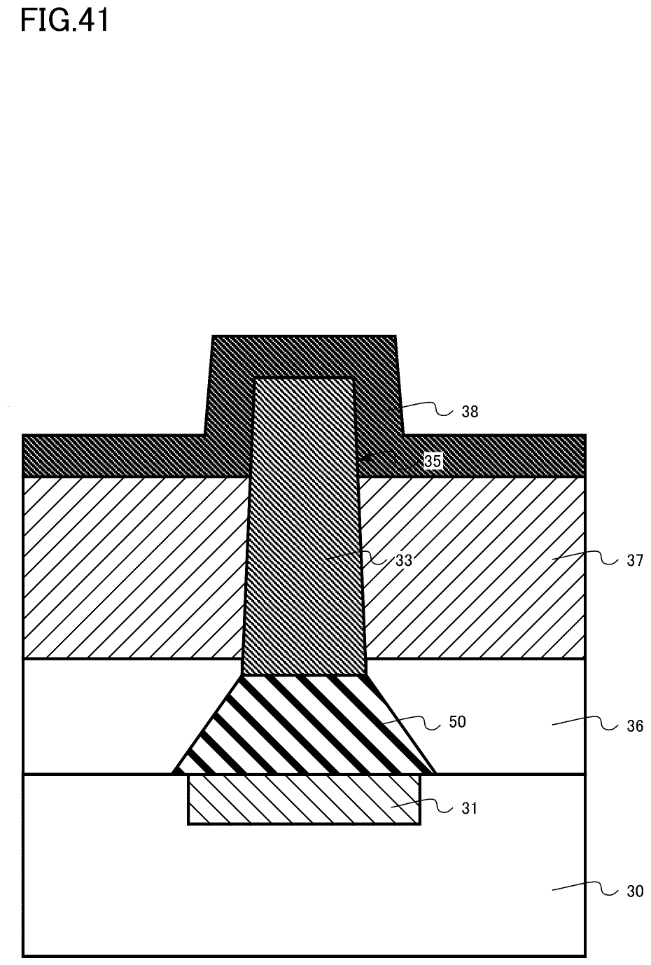

Next, the columnar body 35 is covered with a second silicon nitride film 38 (FIG. 41). The second silicon nitride film 38 is formed by using, for example, the CVD method. The second silicon nitride film 38 is an example of the second insulating film.

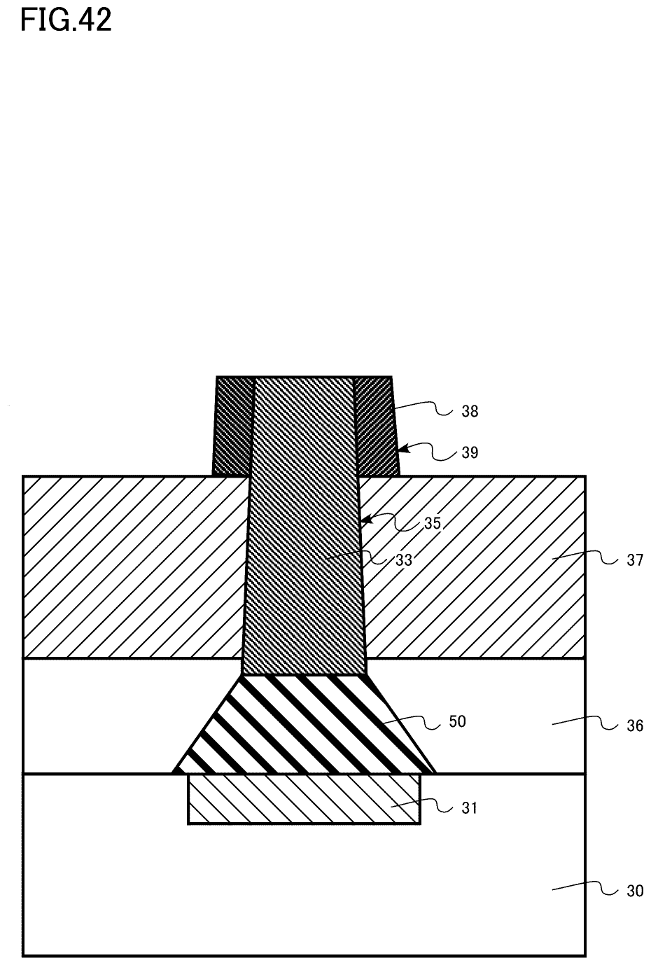

Next, the second silicon nitride film 38 is etched to form a sidewall 39 on a side surface of the columnar body 35 (FIG. 42). The sidewall 39 is formed by using, for example, the RIE method.

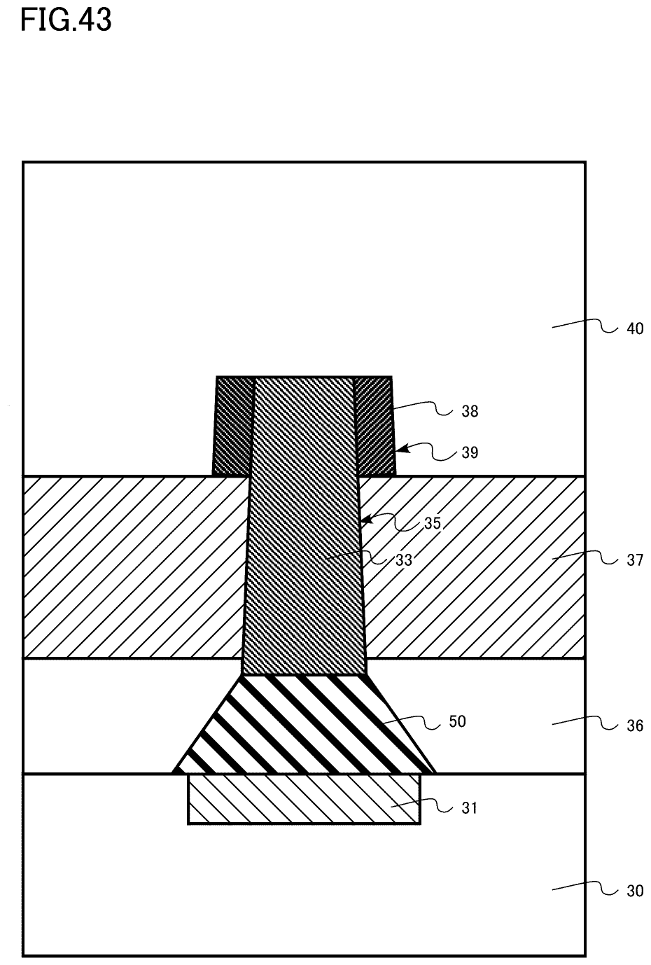

Next, the columnar body 35 and the sidewall 39 are buried with a third silicon oxide film 40 (FIG. 43). The third silicon oxide film 40 is formed by using, for example, the CVD method. The third silicon oxide film 40 is an example of the third insulating film.

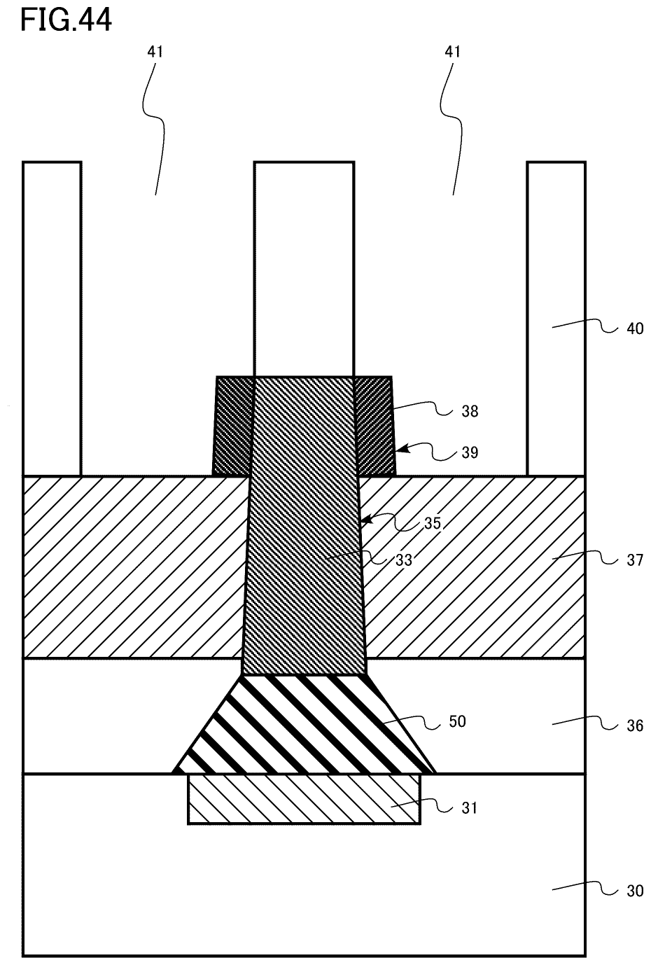

Next, the third silicon oxide film 40 is etched to form a first opening 41 through which the sidewall 39 and the tungsten film 37 are exposed (FIG. 44). The first opening 41 is formed by using the lithography method and the RIE method.

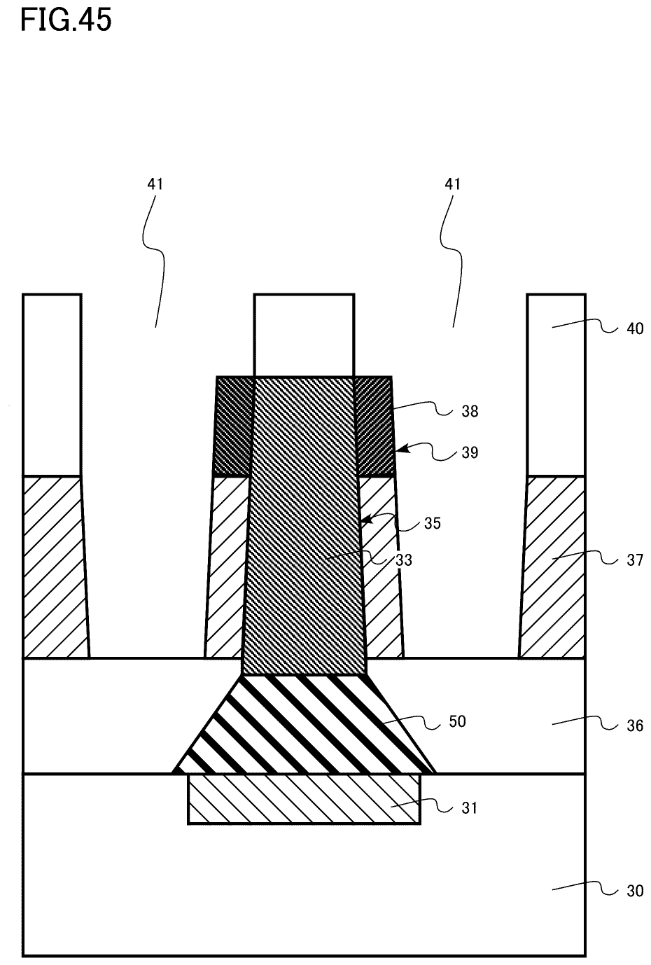

Next, the tungsten film 37 is etched using the third silicon oxide film 40 and the sidewall as a mask (FIG. 45).

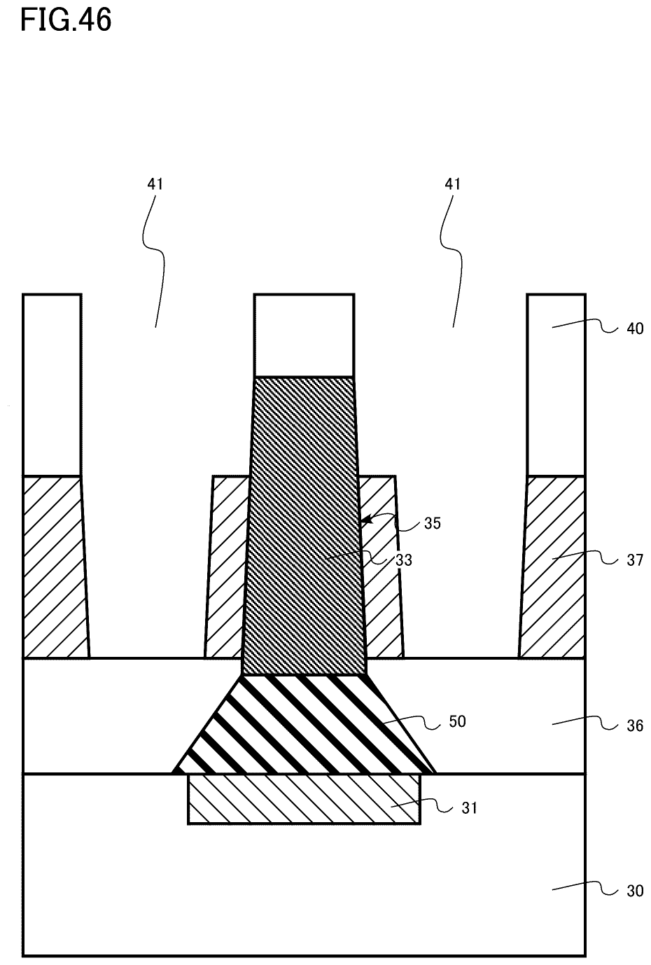

Next, the sidewall 39 is removed (FIG. 46). The sidewall 39 is removed by using, for example, a wet etching method.

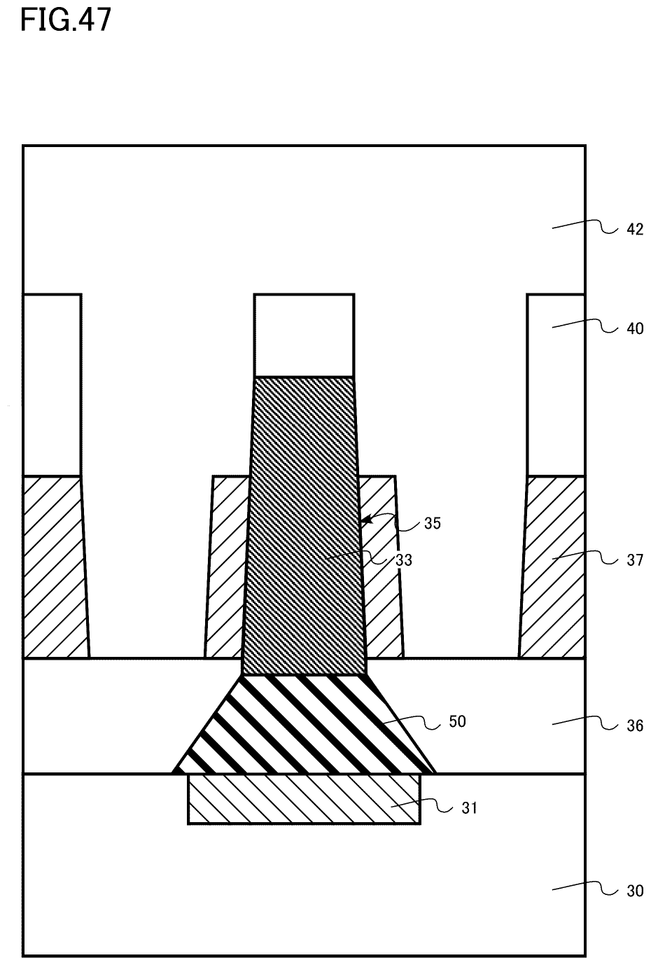

Next, the first opening 41 is buried with a fourth silicon oxide film 42 (FIG. 47). The fourth silicon oxide film 42 is formed by, for example, the CVD method. The fourth silicon oxide film 42 is an example of the fourth insulating film.

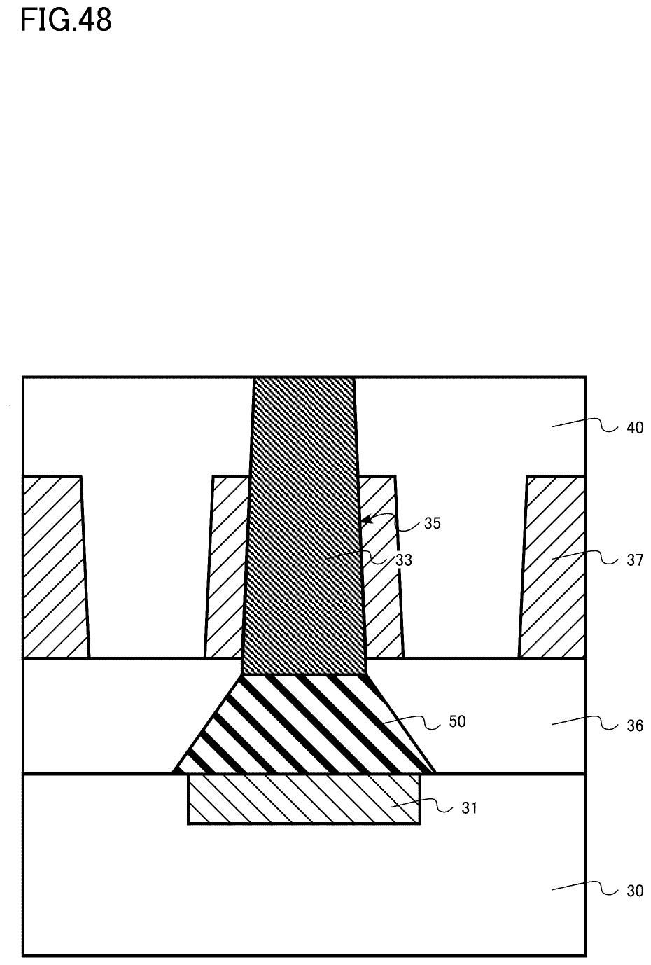

Next, the fourth silicon oxide film 42 on the columnar body 35 is removed to expose a top surface of the columnar body 35 (FIG. 48). The fourth silicon oxide film 42 is removed by using, for example, the CMP method.

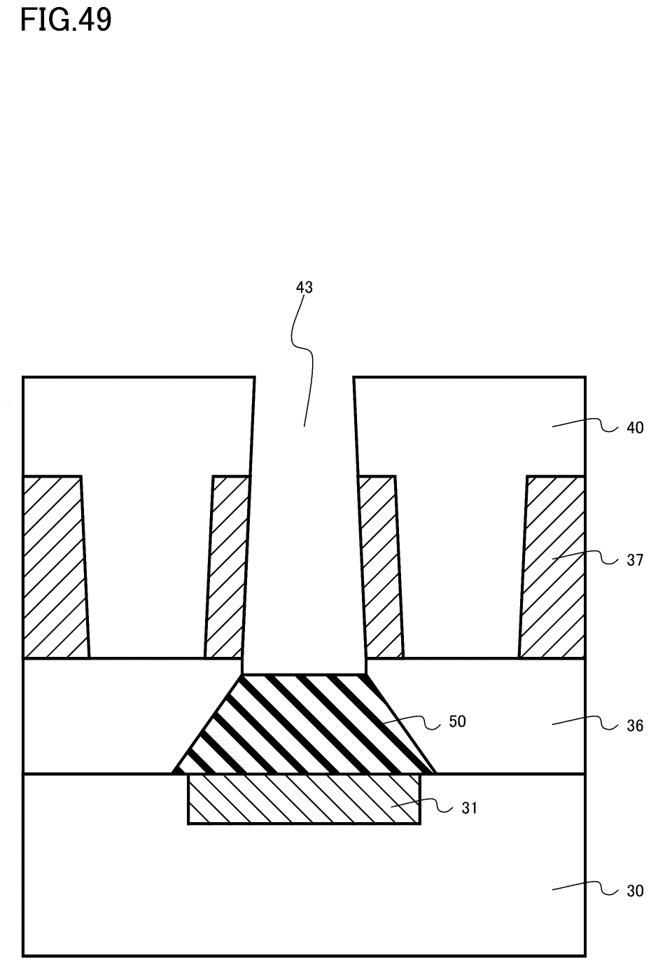

Next, the columnar body 35 is etched and removed to form a second opening 43 through which the tungsten film 37 is exposed on the side surface (FIG. 49). The etching of the amorphous silicon film 33 forming the columnar body 35 is performed by using, for example, the wet etching method. The second opening 43 has a so-called reverse tapered shape.

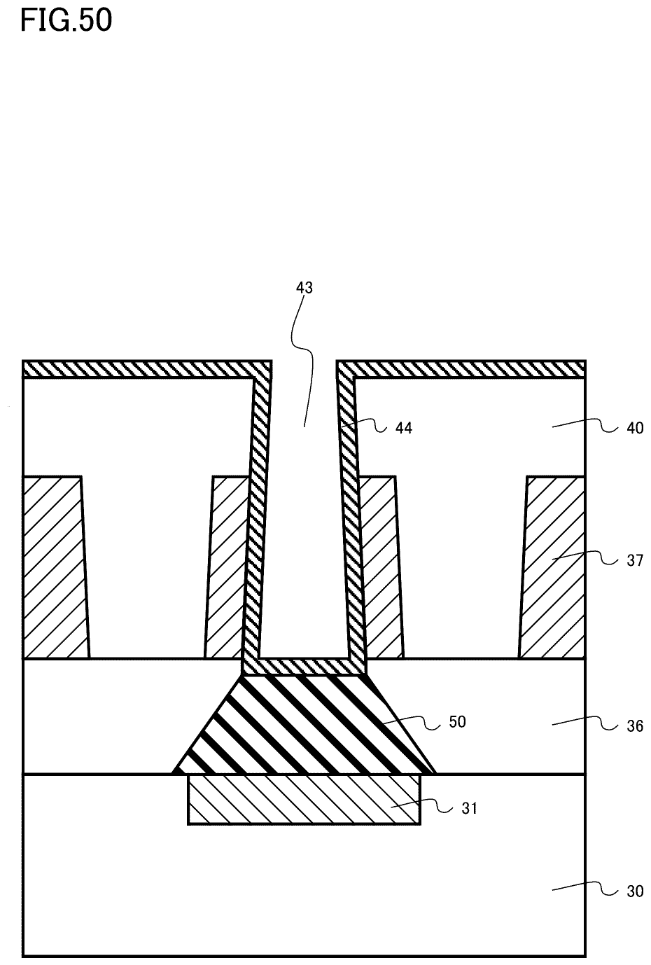

Next, a fourth silicon oxide film 44 is formed in the second opening 43 (FIG. 50). The fourth silicon oxide film 44 is formed by using, for example, the CVD method. The fourth silicon oxide film 44 is an example of the fifth insulating film. A part of the fourth silicon oxide film 44 finally becomes the gate insulating layer 20.

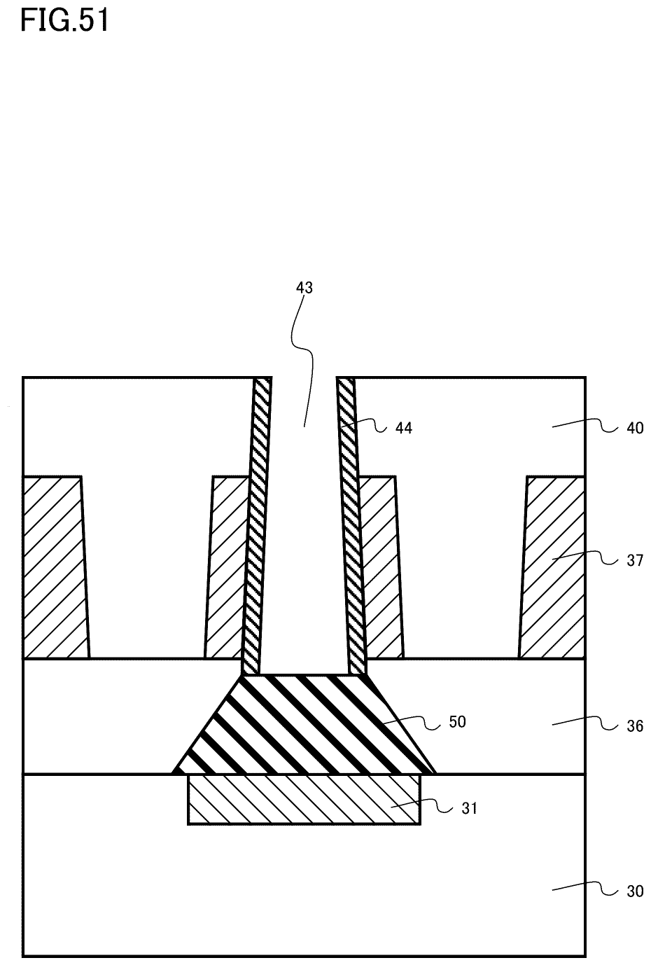

Next, the fourth silicon oxide film 44 at the bottom of the second opening 43 is etched and removed (FIG. 51).

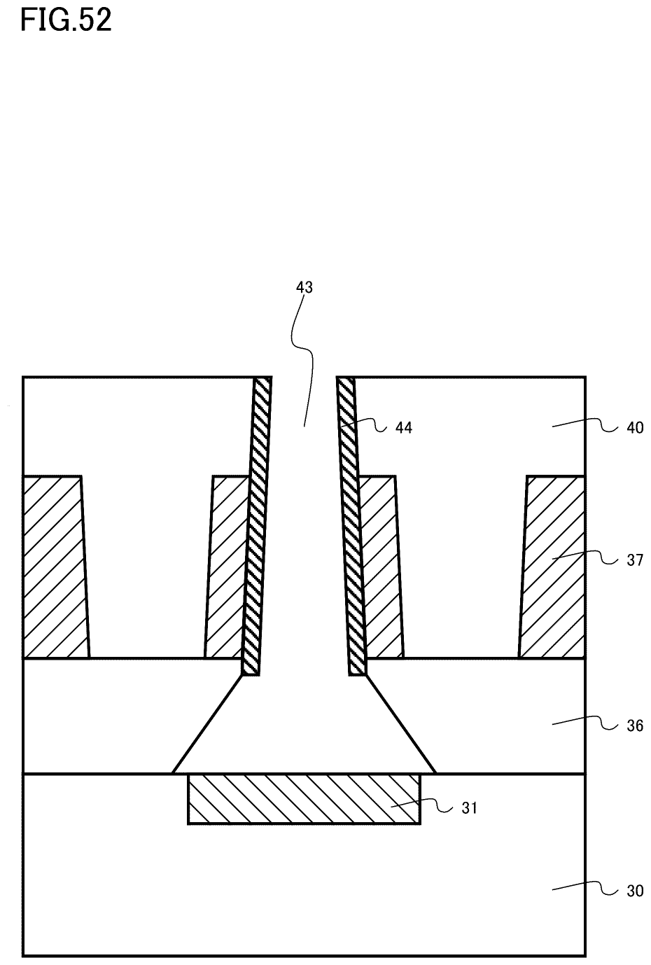

Next, the aluminum oxide film 50 at the bottom of the second opening 43 is etched and removed to expose the surface of the indium tin oxide layer 31 (FIG. 52). The aluminum oxide film 50 is removed by using, for example, the wet etching method.

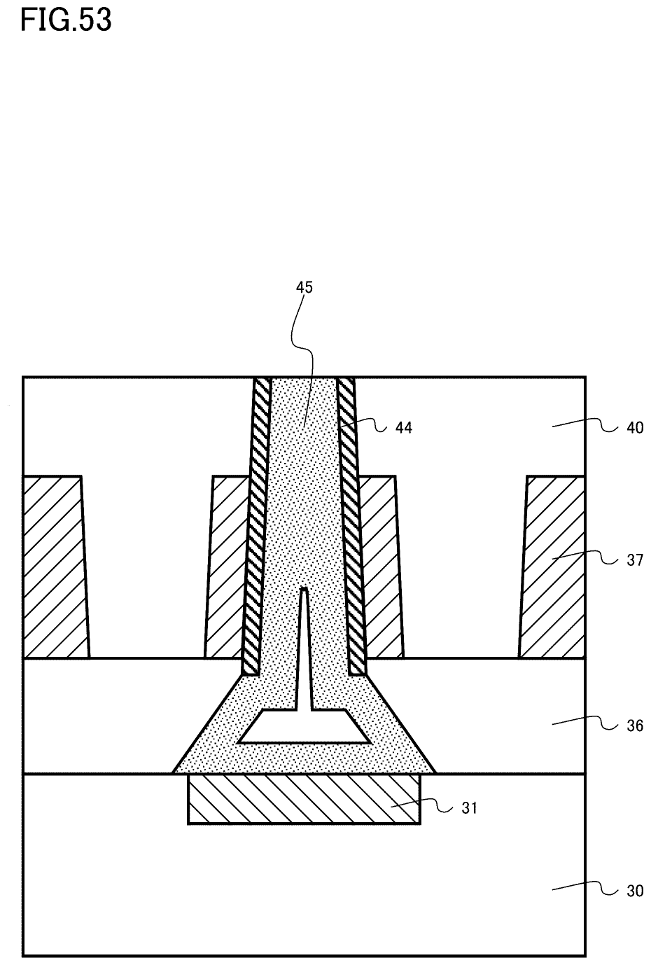

Next, the second opening 43 is buried with an indium gallium zinc oxide film 45 (FIG. 53). The indium gallium zinc oxide film 45 is formed by using, for example, the CVD method and then planarized by using the CMP method. Since the second opening 43 has a reverse tapered shape, a void is formed in the indium gallium zinc oxide film 45 with which the second opening 43 has been buried.

The indium gallium zinc oxide film 45 finally becomes the oxide semiconductor layer 16. The indium gallium zinc oxide film 45 is an example of the semiconductor film.

Then, the upper electrode 14 of the indium tin oxide layer is formed using known process technology.

The transistor 300 illustrated in FIG. 33 is manufactured by the above manufacturing method.

In the example of the above manufacturing method, the amorphous silicon film has been used as the first film. However, for example, a carbon film can also be used as the first film. Although the aluminum oxide film is used as the third film, for example, a hafnium oxide film or a zirconium oxide film can also be used.

Next, functions and effects of the semiconductor device and the method for manufacturing the semiconductor device according to the third embodiment will be described.

As illustrated in FIG. 51, the method for manufacturing the semiconductor device according to the third embodiment has a reverse tapered shape when the fourth silicon oxide film 44 is etched using the RIE method, similarly to the method for manufacturing the semiconductor device according to the first embodiment. Therefore, processing damage does not remain in the fourth silicon oxide film 44. As a result, similarly to the method for manufacturing the semiconductor device according to the first embodiment, the reliability of the gate insulating layer 20 is improved, and the transistor 300 with improved reliability can be realized.

In the method for manufacturing the semiconductor device according to the third embodiment, when the fourth silicon oxide film 44 is etched using the RIE method, as illustrated in FIG. 51, the surface of the indium tin oxide layer 31 is covered with the aluminum oxide film 50 and is not exposed. Therefore, processing damage by RIE does not remain on the surface of the indium tin oxide layer 31. For example, when processing damage remains on the surface of the indium tin oxide layer 31 to be the lower electrode 12, the contact resistance between the oxide semiconductor layer 16 and the lower electrode 12 increases.

According to the method for manufacturing the semiconductor device according to the third embodiment, processing damage by RIE does not remain on the surface of the indium tin oxide layer 31. Therefore, contact resistance between the oxide semiconductor layer 16 and the lower electrode 12 decreases. As a result, a transistor that reduces on-resistance can be realized.

In the method for manufacturing the semiconductor device according to the third embodiment, the aluminum oxide film 50 is formed between the amorphous silicon film 33 forming the columnar body 35 and the indium tin oxide layer 31. By forming the aluminum oxide film 50, abnormal growth of indium tin oxide is suppressed, and for example, a short circuit failure between the adjacent lower electrodes 12 can be suppressed. Therefore, according to the method for manufacturing the semiconductor device of the third embodiment, for example, the manufacturing yield of the semiconductor device is improved.

In the transistor 300 according to the third embodiment, the first length (L1 in FIG. 33) of the first region 16x of the oxide semiconductor layer 16 in the second direction is larger than the second length (L2 in FIG. 33) of the lower electrode 12 in the second direction. For this reason, for example, the contact area between the oxide semiconductor layer 16 and the lower electrode 12 is increased as compared with the transistor 100 of the first embodiment. Therefore, contact resistance between the oxide semiconductor layer 16 and the lower electrode 12 decreases. As a result, a transistor that reduces on-resistance can be realized.

As described above, according to the semiconductor device and the method for manufacturing the semiconductor device according to the third embodiment, a transistor with improved reliability can be realized similarly to the first embodiment. Further, a transistor with an improved manufacturing yield can be realized. Further, a transistor that reduces the on-resistance can be realized. According to the semiconductor device and the method for manufacturing the semiconductor device according to the third embodiment, a semiconductor device having excellent transistor characteristics can be realized.

### Fourth Embodiment

A semiconductor memory device according to a fourth embodiment includes a semiconductor device according to the first embodiment and a capacitor electrically connected to a first electrode.

The semiconductor memory device according to the fourth embodiment is a semiconductor memory 400. The semiconductor memory device according to the fourth embodiment is a DRAM. The semiconductor memory 400 uses the transistor 100 according to the first embodiment as a switching transistor of a memory cell of the DRAM.

Hereinafter, description of contents overlapping with those of the first embodiment will be partially omitted.

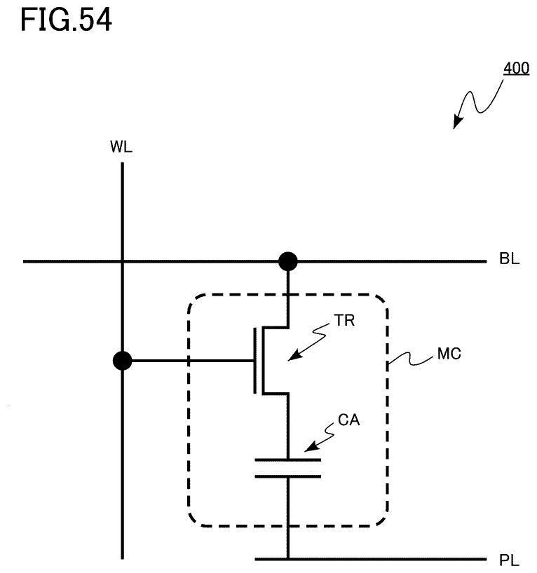

FIG. 54 is an equivalent circuit diagram of the semiconductor memory device according to the fourth embodiment. FIG. 54 illustrates a case where there is one memory cell MC, but a plurality of memory cells MC may be provided in an array, for example.

The semiconductor memory 400 includes a memory cell MC, a word line WL, a bit line BL, and a plate line PL. The memory cell MC includes a switching transistor TR and a capacitor CA. In FIG. 54, a region surrounded by a broken line is the memory cell MC.

The word line WL is electrically connected to a gate electrode of the switching transistor TR. The bit line BL is electrically connected to one of source and drain electrodes of the switching transistor TR. One electrode of the capacitor CA is electrically connected to the other of the source and drain electrodes of the switching transistor TR. The other electrode of the capacitor CA is connected to the plate line PL.

The memory cell MC stores data by accumulating charges in the capacitor CA. Data is written and read by turning on the switching transistor TR.

For example, the switching transistor TR is turned on in a state where a desired voltage is applied to the bit line BL, and data is written to the memory cell MC.

In addition, for example, the switching transistor TR is turned on, a voltage change of the bit line BL according to the charge amount accumulated in the capacitor is detected, and data of the memory cell MC is read.

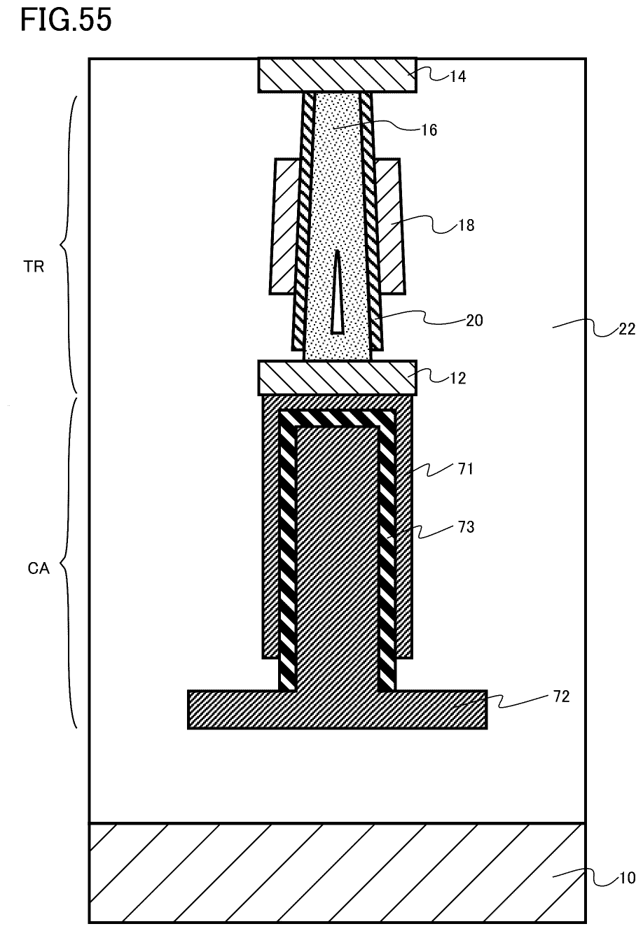

FIG. 55 is a schematic cross-sectional view of the semiconductor memory device of the fourth embodiment. FIG. 55 illustrates a cross section of the memory cell MC of the semiconductor memory 400.

The semiconductor memory 400 includes a silicon substrate 10, a switching transistor TR, a capacitor CA, and an interlayer insulating layer 22.

The switching transistor TR includes a lower electrode 12, an upper electrode 14, an oxide semiconductor layer 16, a gate electrode 18, and a gate insulating layer 20.

The switching transistor TR has a structure similar to that of the transistor 100 of the first embodiment.

The capacitor CA is provided between the silicon substrate 10 and the switching transistor TR. The capacitor CA is provided between the silicon substrate 10 and the lower electrode 12. The capacitor CA is electrically connected to the lower electrode 12.

The capacitor CA includes a cell electrode 71, a plate electrode 72, and a capacitor insulating film 73. The cell electrode 71 is electrically connected to the lower electrode 12. The cell electrode 71 is in contact with the lower electrode 12, for example.

The cell electrode 71 and the plate electrode 72 are, for example, titanium nitride. The capacitor insulating film 73 has, for example, a stacked structure of zirconium oxide, aluminum oxide, and zirconium oxide.

The gate electrode 18 is electrically connected to, for example, a word line WL (not illustrated). The upper electrode 14 is electrically connected to, for example, a bit line BL (not illustrated). The plate electrode 72 is connected to, for example, a plate line PL (not illustrated).

In the semiconductor memory 400, an oxide semiconductor transistor having an extremely small channel leakage current at the time of OFF operation is applied to the switching transistor TR. Therefore, a DRAM having excellent charge retention characteristics is realized.

In addition, the switching transistor TR of the semiconductor memory 400 has high reliability of the gate insulating layer 20. Therefore, the reliability of the semiconductor memory 400 is improved.

In the fourth embodiment, the semiconductor memory to which the transistor of the first embodiment is applied has been described as an example, but the semiconductor memory of the embodiment of the present disclosure may be a semiconductor memory to which the transistor of the third embodiment is applied.

According to the semiconductor memory device of the fourth embodiment, a semiconductor memory device having excellent transistor characteristics can be realized.

While certain embodiments have been described, these embodiments have been presented by way of example only, and are not intended to limit the scope of the inventions. Indeed, the semiconductor device, the semiconductor memory device, and the method for manufacturing the semiconductor device described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor device comprising:
a first electrode;
a second electrode;
an oxide semiconductor layer provided between the first electrode and the second electrode;
a gate electrode facing the oxide semiconductor layer; and
a gate insulating layer provided between the gate electrode and the oxide semiconductor layer, wherein
in a first cross section parallel to a first direction connecting the first electrode and the second electrode,
the gate electrode includes a first portion and a second portion,
the oxide semiconductor layer is provided between the first portion and the second portion in a second direction perpendicular to the first direction,
the first portion has a first end portion on a side of the first electrode and a second end portion on a side of the second electrode, the first end portion having a first end point in contact with the gate insulating layer and a second end point on an opposite side of the first end point, and the second end portion having a third end point in contact with the gate insulating layer and a fourth end point on an opposite side of the third end point,
the second portion has a third end portion on a side of the first electrode and a fourth end portion on a side of the second electrode, the third end portion having a fifth end point in contact with the gate insulating layer and a sixth end point on an opposite side of the fifth end point, and the fourth end portion having a seventh end point in contact with the gate insulating layer and an eighth end point on an opposite side of the seventh end point, and
a first distance between the first end point and the fifth end point is larger than a second distance between the third end point and the seventh end point, and a third distance between the second end point and the sixth end point is larger than a fourth distance between the fourth end point and the eighth end point.

2. The semiconductor device according to claim 1, wherein in the first cross section, a fifth distance in the second direction of a portion of the oxide semiconductor layer in contact with the first electrode is larger than a sixth distance in the second direction of a portion of the oxide semiconductor layer in contact with the second electrode.

3. The semiconductor device according to claim 2, wherein the fifth distance is 1.1 times or more the sixth distance.

4. The semiconductor device according to claim 1, wherein a first thickness in the first direction of a portion of the first electrode in contact with the oxide semiconductor layer is smaller than a second thickness in the first direction of a portion of the first electrode closest to the gate insulating layer in the first direction.

5. The semiconductor device according to claim 1, wherein the oxide semiconductor layer includes a void.

6. The semiconductor device according to claim 1, wherein the oxide semiconductor layer includes a first region partially in contact with the first electrode, and a first length of the first region in the second direction is larger than a second length of the first electrode in the second direction.

7. The semiconductor device according to claim 1, wherein the first electrode is separated from the gate insulating layer in the first direction.

8. The semiconductor device according to claim 1, wherein the gate electrode surrounds the oxide semiconductor layer.

9. A semiconductor memory device comprising:
the semiconductor device according to claim 1; and
a capacitor electrically connected to the first electrode.

10. A method for manufacturing a semiconductor device, comprising:
forming a first film on a first conductive layer;
etching the first film to form a columnar body in which a first width on a side of the first conductive layer is larger than a second width on an opposite side with regard to the first conductive layer;
burying the columnar body with a first insulating film;
etching a part of the first insulating film to expose a part of the columnar body;
burying the columnar body with a first metal film;
etching a part of the first metal film to expose a part of the columnar body;
covering the columnar body with a second insulating film;
etching the second insulating film to form a sidewall on a side surface of the columnar body;
burying the columnar body and the sidewall with a third insulating film;
etching the third insulating film to form a first opening through which the sidewall and the first metal film are exposed;
etching the first metal film using the third insulating film and the sidewall as a mask;
burying the first opening with a fourth insulating film;
removing the fourth insulating film on the columnar body;
exposing the columnar body;
etching and removing the columnar body to form a second opening through which the first metal film is exposed on a side surface;
forming a fifth insulating film in the second opening;
etching and removing the fifth insulating film at a bottom of the second opening; and
burying the second opening with a semiconductor film.

11. The method for manufacturing a semiconductor device according to claim 10, wherein the first conductive layer is exposed in the etching the fifth insulating film at the bottom of the second opening.

12. The method for manufacturing a semiconductor device according to claim 10, further comprising:
forming a second film having a chemical composition different from a chemical composition of the first film on the first film before the etching the first film,
etching the second film to leave the second film on the columnar body before the etching the first film,
burying the second film in the burying the columnar body and the sidewall with the third insulating film, and
etching and removing the second film after the removing the fourth insulating film on the columnar body, before the exposing the columnar body.

13. The method for manufacturing a semiconductor device according to claim 10, further comprising:
forming a third film having a chemical composition different from a chemical composition of the first film before the forming the first film on the first conductive layer,
etching the third film such that a third width of the third film on a side of the first conductive layer become larger than the first width, after the etching the first film, and
etching the third film to expose the first conductive layer, after the etching the fifth insulating film at the bottom.

14. The method for manufacturing a semiconductor device according to claim 10, wherein the semiconductor film is an oxide semiconductor film.

15. The method for manufacturing a semiconductor device according to claim 10, wherein the first film is an amorphous silicon film or a carbon film.

16. The method for manufacturing a semiconductor device according to claim 12, wherein the second film is a boron carbide film or a boron nitride film.

17. The method for manufacturing a semiconductor device according to claim 13, wherein the third film is an aluminum oxide film.
